(19) United States
(12) Patent Application Publication
(10) Pub. No.: US 2025/0048616 A1
(43) Pub. Date: Feb. 6, 2025

(54) SEMICONDUCTOR DEVICE, THREE-DIMENSIONAL MEMORY DEVICE AND MANUFACTURING METHODS THEREOF

(71) Applicants: SK hynix Inc., Icheon-si (KR); IUCF-HYU (Industry-University Cooperation Foundation Hanyang University), Seoul (KR)

(72) Inventors: Young Wook PARK, Seoul (KR); Wang-chul Shin, Seoul (KR); Sung Jun Kim, Seoul (KR)

(21) Appl. No.: 18/781,843

(22) Filed: Jul. 23, 2024

(30) Foreign Application Priority Data
Aug. 4, 2023 (KR) 10-2023-0102304

(51) Int. Cl. H10B 12/00

(52) U.S. Cl. CPC H10B 12/31; H10B 12/03; H10B 12/05; H10B 12/482

(57) ABSTRACT

Disclosed are semiconductor devices, three-dimensional memory devices, and manufacturing methods thereof. A disclosed semiconductor device is a semiconductor device including a transistor, and the transistor may comprise a polycrystalline layer in which crystal grains are vertically oriented, a channel layer in contact with a side surface of the polycrystalline layer and having a structure in which crystal grains are vertically oriented, a source and a drain provided on a first portion and a second portion of the channel layer, respectively, and a gate for controlling an electrical characteristic of the channel layer. The polycrystalline layer may have a discontinuous structure between the source and the drain, the channel layer may have a continuous structure between the source and the drain, and grain boundaries of the channel layer may be arranged in a direction non-parallel to a channel length direction between the source and the drain.

### CROSS-REFERENCES TO RELATED APPLICATION

The present application claims, under 35 U.S.C. § 119 (a), the benefit of Korean application No. 10-2023-0102304 filed on Aug. 4, 2023, which is herein incorporated by reference in its entirety.

### BACKGROUND

### 1. Field

Embodiments of the present disclosure relate to semiconductor/electronic devices and manufacturing methods thereof, and more particularly, to semiconductor devices, three-dimensional memory devices, and manufacturing methods thereof.

### 2. Description of the Related Art

There is a continuous need to increase performance of semiconductor devices and degree of integration of the semiconductor devices. Arranging unit cells of semiconductor devices two-dimensionally, that is, as a planar type, is reaching its limit in increasing degree of integration of the semiconductor devices. Accordingly, the attempts are being made to develop technologies which greatly increase degree of integration of semiconductor devices by three-dimensionally integrating unit cells of the semiconductor devices. In this regard, various attempts are being made to increase the integration of memory devices such as NAND devices or DRAM devices. In addition, research and development are continuously being conducted to improve performance and operation characteristics of memory devices.

In manufacturing three-dimensional memory devices, for example, a stacked structure in which Si/SiGe structures are repeatedly stacked dozens of times or more is used, but this method has the problems of extremely low productivity, high production costs, and high process difficulty. When stacking at least 50 layers of Si and SiGe, there are problems which are generated because of crystal defects caused by lattice mismatch and defects caused by particles generated during the manufacturing process. In the future, when high-density products having high integration of more than 100 layers is expected, there is a limit that it is not possible to manufacture such a multi-layer stack structure. In addition, in forming such a stacked structure, there are disadvantages that the epitaxial process time is long and the epitaxial process difficulty is high.

Therefore, there is a need for the development of a three-dimensional (3D) memory device which may increase scalability of the device while overcoming the problems and limitations of the existing three-dimensional memory devices which use the stacked structure in which Si/SiGe structures are repeatedly stacked. In the development of the 3D memory device, it is necessary to improve device performance by suppressing leakage current and enhancing mobility, while also ensuring ease of manufacturing and high productivity.

### SUMMARY

The technological object to be achieved by the present invention is to provide a semiconductor device and a three-dimensional memory device that can increase the degree of integration, ensure excellent performance, and also be easy to manufacture, thereby improving productivity.

In addition, the technological object to be achieved by the present invention is to provide a semiconductor device and a three-dimensional memory that can improve performance by suppressing leakage current and enhancing mobility, while ensuring ease of manufacturing and high productivity.

In addition, the technological object to be achieved by the present invention is to provide manufacturing methods of the above-described semiconductor device and three-dimensional memory device.

The objects to be solved by the present invention are not limited to the objects mentioned above, and other objects not mentioned will be understood by those skilled in the art from the description below.

According to one embodiment of the present invention, there is provided a semiconductor device including a transistor, and wherein the transistor includes: a polycrystalline layer in which crystal grains are vertically oriented; a channel layer in contact with a side surface of the polycrystalline layer and having a structure in which crystal grains are vertically oriented; a source and a drain provided on a first portion and a second portion of the channel layer, respectively; and a gate for controlling an electrical characteristic of the channel layer, wherein the polycrystalline layer has a discontinuous structure between the source and the drain, the channel layer has a continuous structure between the source and the drain, and grain boundaries of the channel layer are arranged in a direction non-parallel to a channel length direction between the source and the drain.

The polycrystalline layer may include any one of Si, Ge, and SiGe, and the channel layer may include any one of Si, Ge, and SiGe.

The polycrystalline layer and the channel layer may have a columnar crystal grain structure.

The channel layer may be an epitaxially grown layer.

The channel layer may include a first channel layer in contact with a first side surface of the polycrystalline layer; and a second channel layer in contact with a second side surface of the polycrystalline layer, and each of the first channel layer and the second channel layer may have a continuous structure between the source and the drain.

The polycrystalline layer may include a first polycrystalline layer portion adjacent to the source; and a second polycrystalline layer portion adjacent to the drain, and the first polycrystalline layer portion and the second polycrystalline layer portion may be spaced apart from each other.

The grain boundaries of the channel layer may be arranged in a direction perpendicular to the channel length direction.

A hole region which causes the polycrystalline layer to have the discontinuous structure may be defined between the source and the drain, and the gate may be disposed within the hole region.

A plurality of transistors corresponding to the transistor may be arranged to be spaced apart from each other in a vertical direction, and an insulating layer may be arranged between the plurality of transistors.

According to another embodiment of the present invention, there is provided a manufacturing method of a semiconductor device including transistors comprising: preparing a polycrystalline layer having a structure in which crystal grains are vertically oriented; forming a channel layer having a structure in which crystal grains are vertically oriented by using an epitaxial process from a side surface of the polycrystalline layer; removing a portion of the polycrystalline layer so that the polycrystalline layer has a discontinuous structure in a given direction; and defining a gate for controlling an electrical characteristic of the channel layer, and a source and a drain provided on a first portion and a second portion of the channel layer, respectively, and wherein the polycrystalline layer has the discontinuous structure between the source and the drain, the channel layer has a continuous structure between the source and the drain, and grain boundaries of the channel layer are arranged in a non-parallel direction to a channel length direction between the source and the drain.

The preparing the polycrystalline layer may include forming a semiconductor material layer having an amorphous structure or polycrystalline structure; and heat-treating the semiconductor material layer to grow and vertically orient crystal grains within the semiconductor material layer.

The preparing the polycrystalline layer may further include recessing a portion of the semiconductor material layer after the heat-treatment.

The channel layer may include a first channel layer in contact with a first side surface of the polycrystalline layer; and a second channel layer in contact with a second side surface of the polycrystalline layer, and each of the first channel layer and second channel layer may have a continuous structure between the source and the drain.

The polycrystalline layer may include a first polycrystalline layer portion adjacent to the source; and a second polycrystalline layer portion adjacent to the drain, and the first polycrystalline layer portion and the second polycrystalline layer portion may be spaced apart from each other.

The manufacturing method of the semiconductor device may further include preparing a stack structure in which the polycrystalline layer and an insulating layer are alternately and repeatedly stacked, a plurality of transistors corresponding to the transistor may be arranged to be spaced apart from each other in a vertical direction, and the insulating layer may be disposed between the plurality of transistors.

According to another embodiment of the present invention, a three-dimensional memory device including a plurality of memory cells stacked in a vertical direction, and wherein the memory cell includes a transistor and a capacitor connected thereto, and wherein the transistor includes a polycrystalline layer having a structure in which crystal grains are vertically oriented; a channel layer in contact with a side surface of the polycrystalline layer and having a structure in which crystal grains are vertically oriented; a source and a drain provided on a first portion and a second portion of the channel layer, respectively; and a gate for controlling an electrical characteristic of the channel layer, and wherein the polycrystalline layer has a discontinuous structure between the source and the drain, the channel layer has a continuous structure between the source and the drain, and grain boundaries of the channel layer are arranged in a direction non-parallel to a channel length direction between the source and the drain.

The polycrystalline layer and the channel layer may have a columnar crystal grain structure.

The channel layer may include a first channel layer in contact with a first side surface of the polycrystalline layer; and a second channel layer in contact with a second side surface of the polycrystalline layer, and each of the first channel layer and the second channel layer may have a continuous structure between the source and the drain.

The polycrystalline layer may include a first polycrystalline layer portion adjacent to the source; and a second polycrystalline layer portion adjacent to the drain, and the first polycrystalline layer portion and the second polycrystalline layer portion may be spaced apart from each other.

The grain boundaries of the channel layer may be arranged in a direction perpendicular to the channel length direction.

An insulating layer may be disposed between the plurality of transistors and between the plurality of capacitors.

The three-dimensional memory device may include a plurality of bit lines connected to the plurality of memory cells, respectively, and extending in a horizontal direction.

According to another embodiment of the present invention, there is provided a manufacturing method of three-dimensional memory device comprising: preparing a patterned stack structure including a stack structure pattern in which an insulating layer and a first semiconductor material layer are alternately and repeatedly stacked, wherein the first semiconductor material layer has a structure in which crystal grains are vertically oriented; forming a first recess region by recessing a portion of the first semiconductor material layer in the stack structure pattern; forming a second semiconductor material layer having a structure in which crystal grains are vertically oriented by using an epitaxial process from a side surface of the first semiconductor material layer in the first recess region; forming a first vertical hole in a transistor formation region of the stack structure pattern; forming a gate insulating layer in the first vertical hole; forming a gate filling the first vertical hole; forming an opening in a region adjacent to the transistor formation region of the stack structure pattern and forming a first etched region by recessing the first and second semiconductor material layers exposed by the opening; forming a bit line in the first etched region; forming a second vertical hole in a capacitor formation region of the stack structure pattern; forming a second etched region by recessing the first and second semiconductor material layers exposed by the second vertical hole, defining a polycrystalline layer patterned from the first semiconductor material layer in the transistor formation region, and defining a channel layer patterned from the second semiconductor material layer; and forming a capacitor structure in the second etched region and the second vertical hole, and wherein a source and a drain are provided on a first portion and a second portion of the channel layer, respectively, the polycrystalline layer has a discontinuous structure between the source and the drain, the channel layer has a continuous structure between the source and the drain, and grain boundaries of the channel layer are arranged in a direction non-parallel to a channel length direction between the source and drain.

The preparing the patterned stack structure may include forming a stack structure in which the insulating layer and a semiconductor material layer having an amorphous structure or polycrystalline structure are alternately and repeatedly stacked; heat-treating the semiconductor material layer to grow and vertically orient grains within the semiconductor material layer; and performing a cell patterning process for the stack structure.

The polycrystalline layer and the channel layer may have a columnar crystal grain structure.

The grain boundaries of the channel layer may be arranged in a direction perpendicular to the channel length direction.

The forming the capacitor structure may include forming a first electrode in the second etched region; forming a dielectric layer in the second vertical hole; and forming a second electrode filling the second vertical hole.

According to embodiments of the present disclosure, it is possible to implement a semiconductor device and a three-dimensional memory device that can increase the degree of integration, ensure excellent performance, and also be easy to manufacture, thereby improving productivity. In addition, according to embodiments of the present disclosure, it is possible to implement a semiconductor device and a three-dimensional device that can improve performance by suppressing leakage current and enhancing mobility, while ensuring ease of manufacturing and high productivity. In particular, according to embodiments of the present disclosure, the off-current level may be greatly reduced by suppressing leakage current. This is achieved by forming a channel layer with a structure in which crystal grains are vertically oriented and arranging the grain boundaries of the channel layer in a direction that is non-parallel to the channel length direction. Additionally, mobility characteristics may be improved by enhancing the crystallinity of the channel layer through a local epitaxy process.

In addition, according to embodiments of the present disclosure, compared to existing methods using Si/SiGe stacked structures, it is possible to manufacture a three-dimensional memory device with reduced process difficulty, lower manufacturing costs, and improved performance by using a stack of an insulating layer and a semiconductor material layer. According to one embodiment, the three-dimensional memory device may be configured to include a three-dimensional dynamic random access memory (DRAM) device.

However, the effects of the present invention are not limited to those mentioned above and can be expanded in various ways without departing from the technological spirit and scope of the present invention.

### BRIEF DESCRIPTION OF THE DRAWINGS

FIG. 1 is a perspective diagram for explaining a semiconductor device according to an embodiment of the present disclosure.

FIG. 2 is a perspective diagram for explaining a semiconductor device according to another embodiment of the present disclosure.

FIG. 3 is a plan diagram for explaining a semiconductor device according to another embodiment of the present disclosure.

FIG. 4A to FIG. 4D are perspective diagrams for explaining a manufacturing method of a semiconductor device according to an embodiment of the present disclosure.

FIG. 5A to FIG. 5F are plan diagrams for explaining a manufacturing method of a semiconductor device according to another embodiment of the present disclosure.

FIG. 6 is a perspective diagram showing a transistor according to a comparative example.

FIG. 7 and FIG. 8 are cross-sectional diagrams illustrating a three-dimensional memory device according to an embodiment of the present disclosure.

FIG. 9A to FIG. 23B are diagrams for explaining a manufacturing method of a three-dimensional memory device according to an embodiment of the present disclosure.

### DETAILED DESCRIPTION

Hereinafter, embodiments of the present disclosure will be described in detail with reference to the accompanying drawings.

The embodiments of the present disclosure to be described below are provided to more clearly explain the present invention to those skilled in the art, and the scope of the present invention is not limited by the following embodiments, and the embodiments may be modified in many different forms.

The terms used in this specification are used to describe specific embodiments and are not intended to limit the present invention. The terms indicating a singular form used herein may include plural forms unless the context clearly indicates otherwise. Also, as used herein, the terms, “comprise” and/or “comprising” specify the presence of the stated shape, step, number, operation, member, element, and/or group thereof and does not exclude the presence or addition of one or more other shapes, steps, numbers, operations, elements, elements and/or groups thereof. In addition, the term, “connection” used in this specification means not only a direct connection of certain members, but also a concept including an indirect connection in which other members are interposed between the members.

In addition, in the description of this specification, the descriptions such as “first” and “second,” “upper or top,” and “lower or bottom” are intended to distinguish members, and not used to limit the members themselves or mean a specific order, but rather a relative positional relationship among them, and does not limit specific cases where the other members are directly contacted with the described configuring members or another member is introduced into the interface between them. The same interpretation may be applied to other expressions which describe relationships between the configuring components.

In addition, in the present specification, when a member is said to be located “on” another member, this arrangement includes not only a case in which a member is in contact with another member, but also a case where another member exists between the two members. As used herein, the term, “and/or” includes any one and all combinations of one or more of the listed items. In addition, the terms of degree such as “about” and “substantially” used in the present specification are used as a range of values or degrees, or as a meaning close thereto, taking into account inherent manufacturing and substance tolerances, and exact or absolute numbers provided to aid in the understanding of this application are used to prevent the infringers from unfairly exploiting the stated disclosure.

A size or a thickness of regions or parts shown in the accompanying drawings may be slightly exaggerated for clarity of the specification and convenience of description. The same reference numbers indicate the same configuring elements throughout the detailed description.

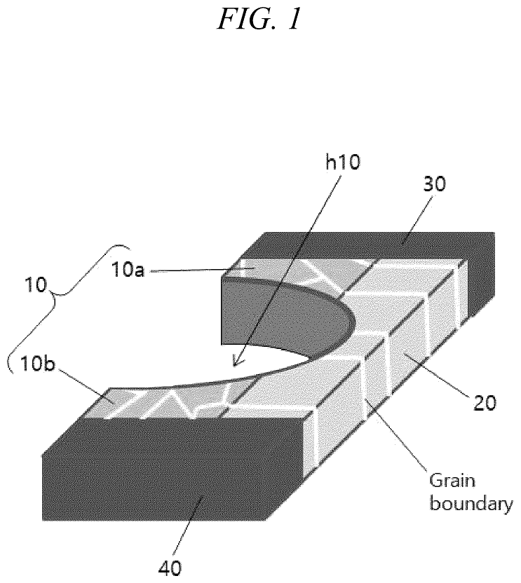

FIG. 1 is a perspective diagram for explaining a semiconductor device according to an embodiment of the present disclosure.

Referring to FIG. 1, the semiconductor device may include a transistor. The transistor may include a polycrystalline layer 10 with vertically oriented crystal grains, and a channel layer 20, which is in contact with a side surface of the polycrystalline layer 10 and also has vertically oriented crystal grains. The crystal grains of the polycrystalline layer 10 may have a vertically oriented structure and may have a thickness corresponding to a thickness of the polycrystalline layer 10. For example, each crystal grain of the polycrystalline layer 10 may have a size that is greater than or equal to the thickness of the polycrystalline layer 10. All crystal grains of the polycrystalline layer 10 may have the vertically oriented structure. Similarly, the crystal grains of the channel layer 20 may have a vertically oriented structure and may have a thickness corresponding to a thickness of the channel layer 20. For example, each crystal grain of the channel layer 20 may have a size that is greater than or equal to the thickness of the channel layer 20. All crystal grains of the channel layer 20 may have the vertically oriented structure.

The transistor may further include a source 30 and a drain 40 provided on (in) a first portion and a second portion of the channel layer 20 in a channel length direction (i.e., a current flow direction), respectively, and may further include a gate (not shown) for controlling the electrical characteristic of the channel layer 20. The source 30 and the drain 40 may be disposed to contact the first portion and the second portion of the channel layer 20, respectively, or may be formed within the first portion and the second portion. The first portion and the second portion of the channel layer 20 may correspond to opposite ends or may be any two portions spaced apart from each other in the channel length direction. The source 30 may include a first electrode layer or a first electrode region, and the drain 40 may include a second electrode layer or a second electrode region. The source 30 and the drain 40 may be formed of a conductive film or may be formed by doping. The channel layer 20 and the polycrystalline layer 10 may be disposed between the source 30 and the drain 40 in the channel length direction. The source 30 may be provided in contact with or within a region of the channel layer 20 and a region of the polycrystalline layer 10 adjacent thereto. The drain 40 may be provided in contact with or within another region of the channel layer 20 and another region of the polycrystalline layer 10 adjacent thereto.

The polycrystalline layer 10 may exhibit a discontinuous structure between the source 30 and the drain 40, while the channel layer 20 may possess a continuous structure between the source 30 and the drain 40. In other words, the polycrystalline layer 10 may feature a non-connection type structure, where it does not establish a connection between the source 30 and the drain 40, while the channel layer 20 may exhibit a connection type structure, serving as the channel between the source 30 and the drain 40. Consequently, the polycrystalline layer 10 may not function as the channel between the source 30 and the drain 40, whereas the channel layer 20 may function as the channel between the source 30 and the drain 40.

According to an embodiment of the present disclosure, grain boundaries of the channel layer 20 may be arranged in a direction that is non-parallel to the channel length direction between the source 30 and the drain 40. That is, the grain boundaries of the channel layer 20 may not be arranged in the channel length direction. The grain boundaries of the channel layer 20 may be arranged so as not to form a current path in the channel length direction. The grain boundaries of the channel layer 20 may not be arranged in a direction that facilitates the connection between the source 30 and the drain 40. One grain boundary or two or more grain boundaries may not be arranged to connect the source 30 and the drain 40 to each other. All grain boundaries of the channel layer 20 may be arranged in a direction that is non-parallel to the channel length direction. Specifically, all grain boundaries of the channel layer 20 may be arranged to cross the channel layer 20 in a channel width direction or a similar direction. The channel width direction may be substantially perpendicular to the channel length direction. Both the channel width direction and the channel length direction may be perpendicular to a vertical direction with respect to the orientation shown in FIG. 1.

According to one embodiment, the polycrystalline layer 10 may be a layer containing a semiconductor material. The polycrystalline layer 10 may be a semiconductor material layer. For example, the polycrystalline layer 10 may include any one of Si, Ge, and SiGe or may be formed of any one of Si, Ge, and SiGe. The channel layer 20 may be a layer containing a semiconductor material. The channel layer 20 may be a semiconductor material layer. For example, the channel layer 20 may include any one of Si, Ge, and SiGe or may be formed of any one of Si, Ge, and SiGe. The material of the channel layer 20 may be the same as or different from the material of the polycrystalline layer 10.

The channel layer 20 may be a separate material layer from the polycrystalline layer 10. The polycrystalline layer 10 may serve as a seed layer for forming the channel layer 20. The channel layer 20 may be an epitaxial growth layer (i.e., an epitaxial layer) grown from the polycrystalline layer 10. The crystal grains of the channel layer 20 may grow oriented in a predetermined direction. The channel layer 20 may be formed by a local epitaxy process and may have a quasi-single crystal structure.

According to one embodiment, the polycrystalline layer 10 and the channel layer 20 may have a columnar crystal grain structure. The crystal grains of the polycrystalline layer 10 may have a columnar structure oriented in the vertical direction, and similarly, the crystal grains of the channel layer 20 may have a columnar structure oriented in the vertical direction. Therefore, a horizontally extending grain boundary may not exist in the polycrystalline layer 10, and similarly, a horizontally extending grain boundary may not exist in the channel layer 20.

According to one embodiment, the grain boundaries of the channel layer 20 may be arranged in a direction perpendicular to or substantially perpendicular to the channel length direction. All grain boundaries of the channel layer 20 may be arranged in the direction perpendicular to or substantially perpendicular to the channel length direction. According to one embodiment, the grain boundaries of the channel layer 20 may be arranged in a direction parallel or substantially parallel to the channel width direction. However, the orientation direction of the grain boundaries of the channel layer 20 may vary within a range that satisfies a direction which is non-parallel to the channel length direction.

According to one embodiment, the polycrystalline layer 10 may include a first polycrystalline layer portion 10a adjacent to the source 30 and a second polycrystalline layer portion 10b adjacent to the drain 40. In this case, the first polycrystalline layer portion 10a and the second polycrystalline layer portion 10b may be arranged to be spaced apart from each other in the channel length direction. For example, a hole region h10, which causes the polycrystalline layer 10 to have the discontinuous structure, i.e., the non-connection type structure, may be defined between the source 30 and the drain 40. The first polycrystalline layer portion 10a and the second polycrystalline layer portion 10b may be spaced apart from each other by the hole region h10. Furthermore, although not shown in FIG. 1, the gate of the transistor may be disposed within the hole region h10. A gate insulating layer may be formed on an inner surface of the hole region h10, and a gate electrode may be formed on the gate insulating layer to fill the hole region h10. Here, in FIG. 1, the hole region h10 is shown in a round shape, but the shape of the hole region h10 may vary in different ways.

According to the embodiment of the present disclosure, because the grain boundaries of the channel layer 20 may be arranged in the direction non-parallel to the channel length direction (i.e., the current flow direction) between the source 30 and the drain 40, current leakage due to the grain boundaries may be suppressed or prevented. Therefore, according to the embodiment, a transistor capable of significantly reducing the off-current level by suppressing leakage current, along with a semiconductor device including the same, can be implemented. Meanwhile, since the grain boundary may hardly interfere with the flow of current in the ON state, the issue of on-current being hindered by the grain boundary may rarely occur. That is, in the ON state, as a channel formation effect appears and an inversion region is formed, the problem of the grain boundaries impeding on-current may rarely occur.

In addition, according to the embodiment of the present disclosure, the crystallinity of the channel layer 20 may be enhanced through the local epitaxy process to form the quasi-single crystal structure, thereby improving mobility characteristics. Therefore, according to the embodiment, a transistor with enhanced mobility characteristics and a semiconductor device including the same can be implemented.

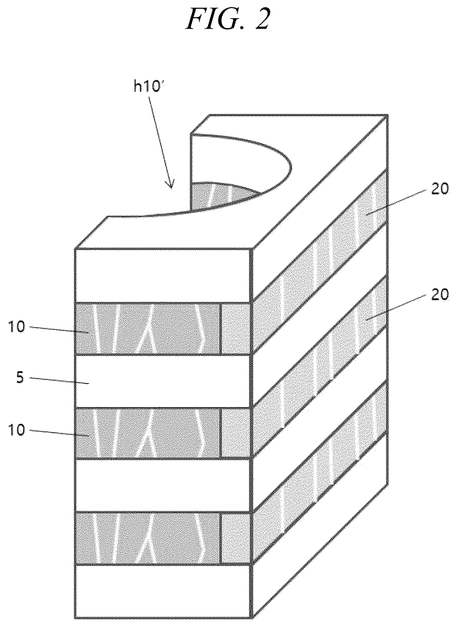

According to another embodiment of the present disclosure, a plurality of transistors each corresponding to the above-mentioned transistor may be arranged to be spaced apart from each other in the vertical direction, and insulating layers may be disposed between the plurality of transistors, which is shown in FIG. 2.

FIG. 2 is a perspective diagram for explaining a semiconductor device according to another embodiment of the present disclosure.

Referring to FIG. 2, a plurality of transistors, each described with reference to FIG. 1, may be arranged to be vertically spaced apart from each other, with an insulating layer 5 disposed between two adjacent transistors among the plurality of transistors. In other words, the insulating layer 5 and the transistor of FIG. 1 may be alternately and repeatedly stacked in the vertical direction. The insulating layer 5 may include one or more of various insulating materials, such as silicon oxide, silicon nitride, silicon oxynitride, low-k materials, and high-k materials. For illustrative convenience, the source 30 and the drain 40 of FIG. 1 are not shown in FIG. 2, but the source 30 and drain 40 may also be applied to FIG. 2. A hole region h10′ may be formed in a direction perpendicular to the stack of FIG. 2, and a gate (not shown) may be disposed within the hole region h10′. The gate may extend in the vertical direction and may form one word line connected to the plurality of transistors.

As shown in FIG. 2, when the plurality of transistors are stacked vertically with the insulating layer 5 disposed between them, a three-dimensional semiconductor device (e.g., a three-dimensional memory device) may be easily implemented.

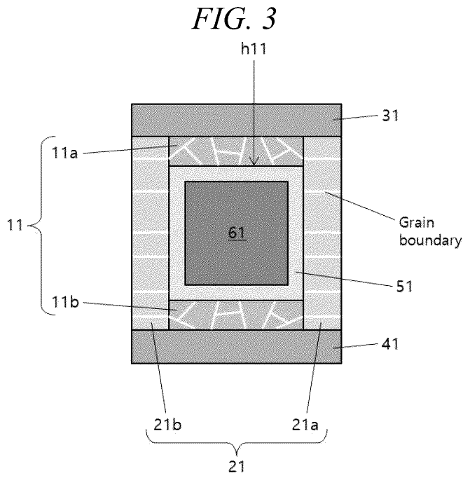

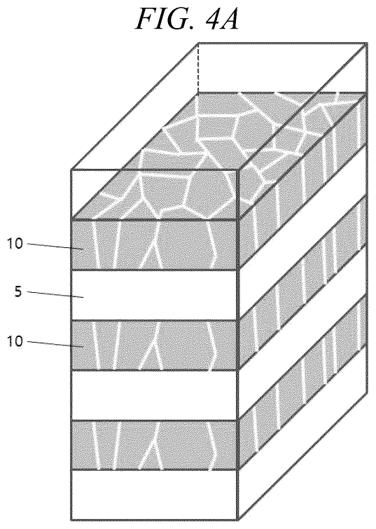

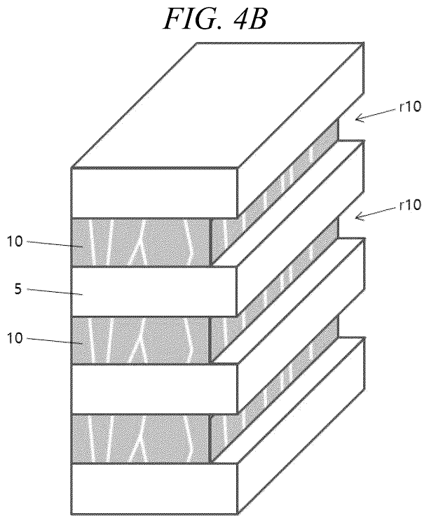

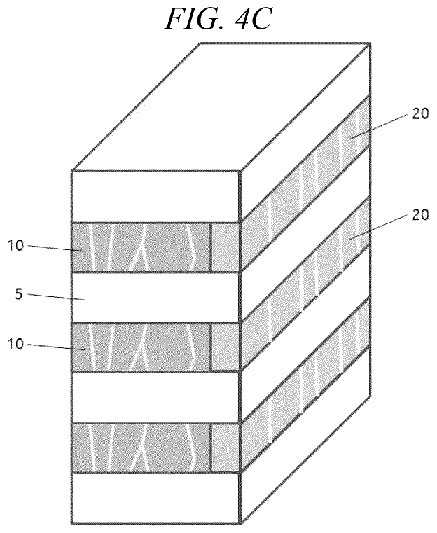

FIG. 3 is a plan diagram for explaining a semiconductor device according to another embodiment of the present disclosure.

Referring to FIG. 3, the semiconductor device may include a transistor, and the transistor may include a polycrystalline layer 11 with vertically oriented crystal grains, a channel layer 21, which is in contact with a side surface of the polycrystalline layer 11 and also has vertically oriented crystal grains, a source 31 and a drain 41 provided on (in) a first portion and a second portion of the channel layer 21, respectively, and a gate 61 for controlling the electrical characteristic of the channel layer 21. In the channel length direction, the polycrystalline layer 11 may have a discontinuous structure (or non-connection type structure) between the source 31 and the drain 41, and the channel layer 21 may have a continuous structure between the source 31 and the drain 41. Grain boundaries of the channel layer 21 may be arranged in a direction non-parallel to the channel length direction between the source 31 and the drain 41.

In this embodiment, the channel layer 21 includes a first channel layer 21a in contact with a first side surface of the polycrystalline layer 11 and a second channel layer 21b in contact with a second side surface of the polycrystalline layer 11. Each of the first and second channel layers 21a and 21b may have a continuous structure (or connection type structure) between the source 31 and the drain 41. The first channel layer 21a may be referred to as a ‘first channel layer portion,’ and the second channel layer 21b may be referred to as a ‘second channel layer portion.’ Each of the first channel layer 21a and the second channel layer and 21b may have all of the characteristics of the channel layer 20 described with reference to FIG. 1. When using the first and second channel layers 21a and 21b, since two current flow paths are generated between the source 31 and the drain 41 through the first and second channel layers 21a and 21b, current flow characteristics of the transistor may be improved.

According to one embodiment, the polycrystalline layer 11 may include a first polycrystalline layer portion 11a adjacent to the source 31 and a second polycrystalline layer portion 11b adjacent to the drain 41. The first polycrystalline layer portion 11a and the second polycrystalline layer portions 11b may be arranged to be spaced apart from each other between the source 31 and the drain 41 in the channel length direction.

A hole region h11 may be defined between the source 31 and the drain 41 to facilitate the formation of the polycrystalline layer 11 as the discontinuous structure and to allow the channel layer 21 to be formed as the continuous structure. Therefore, the first polycrystalline layer portion 11a and the second polycrystalline layer portions 11b may be spaced apart from each other by the hole region h11. The hole region h11 may be defined by the first and second channel layers 21a and 21b and the first and second polycrystalline layer portions 11a and 11b.

A gate insulating layer 51 may be formed on an inner surface of the hole region h11, and the gate 61 may be formed on the gate insulating layer 51 to fill the remaining portion of the hole region h11 after the gate insulating layer 51 is formed. The shape of the hole region h11 may vary in different ways.

The materials, characteristics, and related effects of each component of the transistor shown in FIG. 3 may be the same as or similar to those described for the corresponding component in FIG. 1.

A manufacturing method of a semiconductor device including a transistor according to an embodiment of the present disclosure may include a step for preparing a polycrystalline layer with vertically oriented crystal grains, and a step for forming a channel layer with vertically oriented crystal grains by performing an epitaxial process on the polycrystalline layer, a step for removing a portion of the polycrystalline layer so that the polycrystalline layer has a discontinuous structure in a given direction, and a step for forming a gate for controlling the electrical characteristic of the channel layer in a region where the portion of the polycrystalline layer is removed, and a step for forming a source and a drain on (in) a first portion and a second portion of the channel layer, respectively. Here, in the channel length direction, the polycrystalline layer may have the discontinuous structure between the source and the drain, and the channel layer may have the continuous structure between the source and the drain. Grain boundaries of the channel layer may be arranged in a direction non-parallel to the channel length direction between the source and the drain.

According to one embodiment, the step for preparing the polycrystalline layer may include a step for forming a semiconductor material layer having an amorphous structure or a polycrystalline structure and a step for growing and vertically orienting crystal grains in the semiconductor material layer by heat-treating the semiconductor material layer. Furthermore, the step for preparing the polycrystalline layer may further include a step for forming a recess region by recessing a portion of the semiconductor material layer after the heat-treatment. The channel layer may be formed from the polycrystalline layer through an epitaxial process in the recess region.

According to one embodiment, the polycrystalline layer may include a first polycrystalline layer portion adjacent to the source and a second polycrystalline layer portion adjacent to the drain. The first polycrystalline layer portion and the second polycrystalline layer portion may be arranged to be spaced apart from each other in the channel length direction. In a step for removing a portion of the polycrystalline layer so that the polycrystalline layer may have a discontinuous structure in a given direction, a predetermined hole region may be defined, and the first polycrystalline layer portion and the second polycrystalline layer portion may be spaced apart from each other by the hole region.

In addition, according to one embodiment, the manufacturing method of the semiconductor device may include a step for preparing a stacked structure in which the polycrystalline layer and an insulating layer are alternately and repeatedly stacked in the vertical direction, and in this case, a plurality of transistors, each corresponding to the transistor described above, may be arranged to be spaced apart from each other in the vertical direction, with the insulating layer disposed between every two adjacent transistors in the vertical direction.

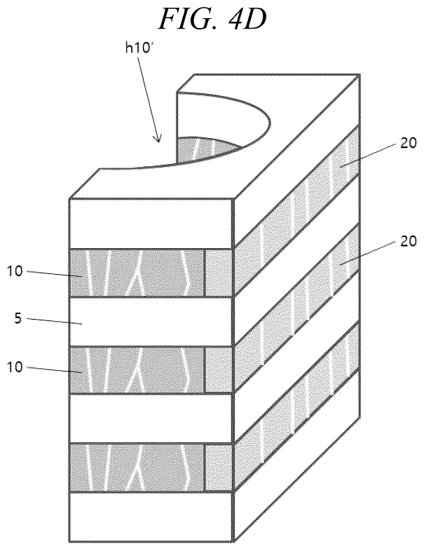

FIG. 4A to FIG. 4D are perspective diagrams for explaining a manufacturing method of a semiconductor device according to an embodiment of the present disclosure.

Referring to FIG. 4A, a stack structure in which an insulating layer 5 and a polycrystalline layer 10 are alternately and repeatedly stacked in the vertical direction may be prepared. The polycrystalline layer 10 may have a structure with vertically oriented crystal grains. For example, the polycrystalline layer 10 may have a columnar crystal grain structure.

For example, after alternately depositing the insulating layer 5 and a semiconductor material layer having an amorphous or polycrystalline structure on a predetermined substrate (not shown), the semiconductor material layer may be transformed into the polycrystalline layer 10 by heat-treating the semiconductor material layer to grow and vertically orient crystal grains within the semiconductor material layer. The stack structure in which the insulating layer 5 and the polycrystalline layer 10 are alternately and repeatedly stacked may be formed through this process.

The semiconductor material layer may include any one of Si, Ge, and SiGe and may be deposited by using a low-pressure chemical vapor deposition (LPCVD) or plasma-enhanced chemical vapor deposition (PECVD) method. For example, the heat-treatment of the semiconductor material layer may be performed at a temperature of about 800° C. or higher. The crystal grains may be grown and vertically oriented within the semiconductor material layer through the heat-treatment.

Referring to FIG. 4B, a portion of the polycrystalline layer 10 may be recessed in a horizontal direction to form a recess region r10, the horizontal direction being substantially perpendicular to the vertical direction. In other words, a portion of the heat-treated semiconductor material layer may be recessed to form the recess region r10. For example, a cell patterning process may be performed on the stack structure in which the insulating layer 5 and the polycrystalline layer 10 are alternately and repeatedly stacked to form an opening, and a portion (or a side portion) of the polycrystalline layer 10 exposed by the opening may be recessed to form the recessed region r10. The recessing process may be performed by injecting a wet etching solution with an etching selectivity between the insulating layer 5 and the polycrystalline layer 10 through the opening, thereby partially etching only the polycrystalline layer 10. The wet etching solution may include potassium hydroxide (KOH), tetra-methyl ammonium hydroxide (TMAH), or the like.

Referring to FIG. 4C, a channel layer 20 may be formed in the recess region r10, grown from a side surface of the polycrystalline layer 10 using an epitaxial process. The channel layer 20 may be grown in the horizontal direction. The channel layer 20 may have a structure with vertically oriented crystal grains. For example, the channel layer 20 may have a columnar crystal grain structure. Furthermore, grain boundaries of the channel layer 20 may be arranged in a direction non-parallel to the channel length direction. For example, the channel layer 20 may include any one of Si, Ge, and SiGe.

For example, by performing selective epitaxial growth in the horizontal direction using the vertically oriented grains of the polycrystalline layer 10 as seeds, vertically oriented grains can be maintained without generating additional grain boundaries in forming the channel layer 20. The selective epitaxial growth may be performed at a temperature of about 600° C. or higher using SiH₄ gas. For the selective epitaxial growth, it may be possible to use SiₓH_{y} gas, and HCl may be injected into the reactor during the growth process to improve selective deposition characteristics. However, embodiments are not limited thereto.

Referring to FIG. 4D, a hole region h10′ may be formed by performing an etching process on the stacked structure corresponding to the result of FIG. 4C. The hole region h10′ may be formed by mainly etching the insulating layer 5 and the polycrystalline layer 10 in the stacked structure. The hole region h10′ may be formed vertically or substantially vertically, and thus each polycrystalline layer 10 may be etched to have a discontinuous structure. A portion of each polycrystalline layer 10 may be etched, so that each polycrystalline layer 10 may be divided into two portions. The two portions have a discontinuous structure in a given direction. When forming the hole region h10′, a portion of the channel layer 20 may be etched, but the channel layer 20 may maintain a continuous structure.

Although not shown, a gate for controlling the electrical characteristics of the channel layer 20, and a source and a drain provided on (in) a first portion and a second portion of the channel layer 20, respectively, may be defined. In the given direction, the polycrystalline layer 10 may have the discontinuous structure between the source and the drain, the channel layer 20 may have the continuous structure between the source and the drain. The grain boundaries of the channel layer 20 may be arranged in a direction non-parallel to the channel length direction between the source and the drain. The given direction may correspond to the channel length direction.

In the manufacturing method of the semiconductor device described with reference to FIGS. 4A to 4D, the order of steps may vary within a consistent range. In addition, the materials and temperature conditions specifically disclosed in the description of FIGS. 4A to 4D are merely examples and may be varied in different ways.

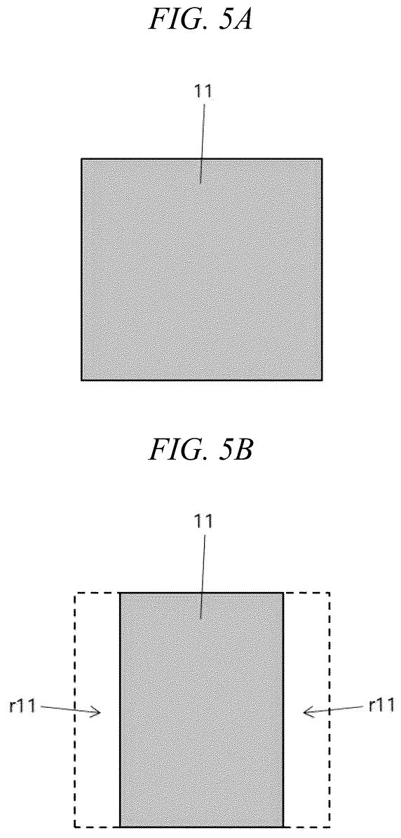

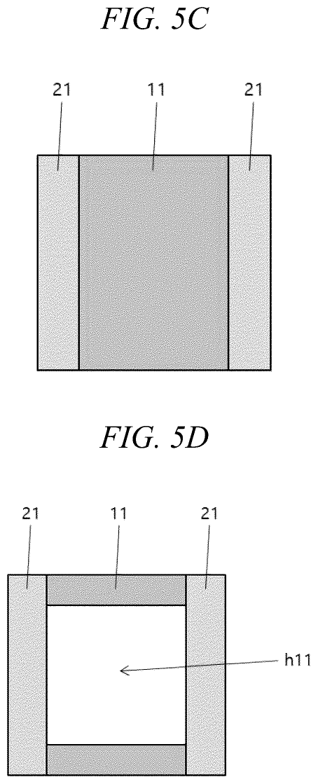

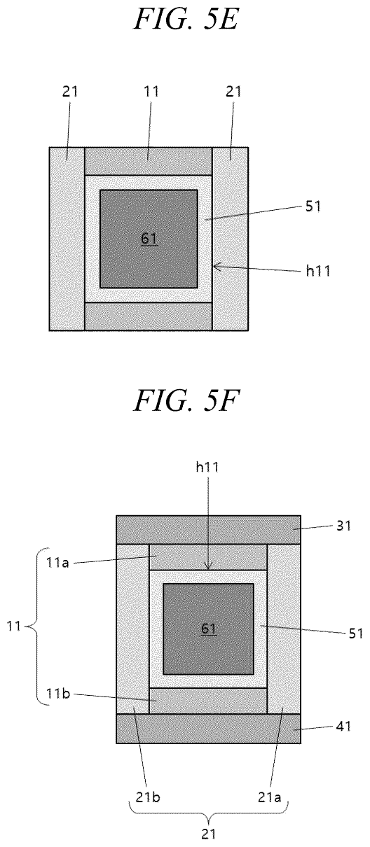

FIG. 5A to FIG. 5F are plan diagrams for explaining a manufacturing method of a semiconductor device according to another embodiment of the present disclosure.

Referring to FIG. 5A, a polycrystalline layer 11 having a structure with vertically oriented crystal grains may be prepared. The step for preparing the polycrystalline layer 11 may include a step for forming a semiconductor material layer having an amorphous structure or polycrystalline structure and a step for heat-treating the semiconductor material layer to grow vertically oriented crystal grains within the semiconductor material layer. The step for preparing the polycrystalline layer 11 may be the same as or similar to the corresponding step of the method described with reference to FIG. 4A.

Referring to FIG. 5B, a portion of the polycrystalline layer 11 may be recessed in the horizontal direction to form a recess region r11. For example, both sides of the polycrystalline layer 11 may be recessed to form two recess regions r11 on both sides of the polycrystalline layer 11.

Referring to FIG. 5C, a channel layer 21 may be formed in each of the two recess regions r11, grown from each side surface of the polycrystalline layer 11 using an epitaxial process. The channel layer 21 may have a structure with vertically oriented crystal grains. Furthermore, the grain boundaries of the channel layer 21 may be arranged in a direction non-parallel to the channel length direction.

Referring to FIG. 5D, a portion of the polycrystalline layer 11 may be etched to form a hole region h11. The hole region h11 may be formed vertically or substantially vertically, and may divide the polycrystalline layer 11 into two portions so that the two portions of the polycrystalline layer 11 may have a discontinuous structure in a given direction that corresponds to the channel length direction. As a result, the hole region h11 may be defined by the two portions of the polycrystalline layer 11 and the two channel layers 21 formed in the two recess regions r11.

Referring to FIG. 5E, a gate insulating layer 51 may be formed on an inner surface of the hole region h11. A gate 61 may be formed on the gate insulating layer 51 to fill the remaining portion of the hole region h11 after the gate insulating layer 51 is formed.

Referring to FIG. 5F, a source 31 and a drain 41 provided on both sides of the channel layer 21 in the channel length direction may be defined (or formed), respectively. The two portions of the polycrystalline layer 11 may have a discontinuous structure between the source 31 and the drain 41, each of the two channel layers 21 may have a continuous structure between the source 31 and the drain 41, and the grain boundaries of the channel layer 21 may be arranged in a direction non-parallel to the channel length direction between the source 31 and the drain 41.

The two portions of the polycrystalline layer 11 may include a first polycrystalline layer portion 11a adjacent to the source 31 and a second polycrystalline layer portion 11b adjacent to the drain 41, and the first and the second polycrystalline layer portions 11a and 11b may be placed spaced apart from each other in the channel length direction. The first and the second polycrystalline layer portions 11a and 11b may be spaced apart from each other by the hole region h11. The two channel layers 21 may include a first channel layer 21a in contact with first side surfaces of the first and second polycrystalline layer portions 11a and 11b and a second channel layer 21b in contact with second side surfaces of the first and second polycrystalline layer portions 11a and 11b. Each of the first and the second channel layers 21a and 21b may have a continuous structure between the source 31 and the drain 41.

Although not shown, a plurality of transistors, each corresponding to the transistor shown in FIG. 5F, may form a stacked structure with an insulating layer interposed between every two adjacent transistors in the vertical direction. Since this may be easily seen from the method described with reference to FIGS. 4A to 4D, detailed description thereof will be omitted. Furthermore, the order of steps in the method of manufacturing the semiconductor device described with reference to FIGS. 5A to 5F may vary within a consistent range.

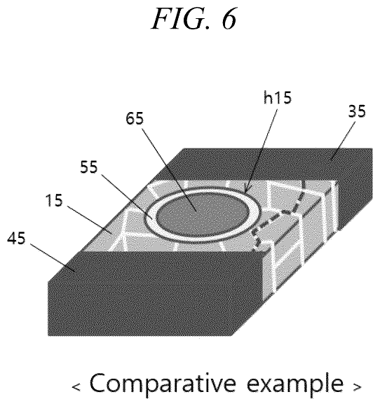

FIG. 6 is a perspective diagram showing a transistor according to a comparative example.

Referring to FIG. 6, the transistor according to the comparative example includes a channel layer 15, a source 35, a drain 45, a gate insulating layer 55, and a gate 65. The gate insulating layer 55 and the gate 65 may be formed in a hole region h15 formed in the channel layer 15. The channel layer 15 may have a structure which surrounds the gate 65 and connects the source 35 and the drain 45. The channel layer 15 may include a polysilicon layer. The grain boundaries of the channel layer 15 may be arranged to form a current path in the channel length direction between the source 35 and the drain 45. The grain boundaries that form the aforementioned current path may cause problems such as generating leakage current and increasing off-current. Furthermore, since the improvement in crystallinity of the channel layer 15 is limited in the stacked structure, there is a problem where the mobility characteristic of the channel layer 15 deteriorates.

On the other hand, according to embodiments of the present disclosure, it is possible to implement a semiconductor device that improves performance by suppressing leakage current and enhancing mobility. In particular, according to embodiments of the present disclosure, a channel layer with vertically oriented crystal grains is formed, and the grain boundaries of the channel layer are arranged in a direction non-parallel to the channel length direction. As a result, the off-current level can be remarkably lowered by suppressing leakage current, and the mobility characteristics can be improved by enhancing the crystallinity of the channel layer through a local epitaxy process.

The transistors according to embodiments of the present disclosure may be applied to three-dimensional memory devices. A three-dimensional memory device according to one embodiment may include a plurality of memory cells stacked in the vertical direction. A memory cell may include a transistor and a capacitor connected to the transistor. The transistor may have structural characteristics and manufacturing method characteristics as described above with reference to FIGS. 1 to 5F. The transistor may include a polycrystalline layer with vertically oriented crystal grains, a channel layer in contact with a side surface of the polycrystalline layer, featuring a structure where crystal grains are vertically oriented, a source and a drain provided on (in) a first portion and a second portion of the channel layer, respectively, and a gate for controlling the electrical characteristic of the channel layer. The polycrystalline layer may have a discontinuous structure between the source and the drain, the channel layer may have a continuous structure between the source and the drain, and grain boundaries of the channel layer may be arranged in a direction non-parallel to the channel length direction between the source and the drain.

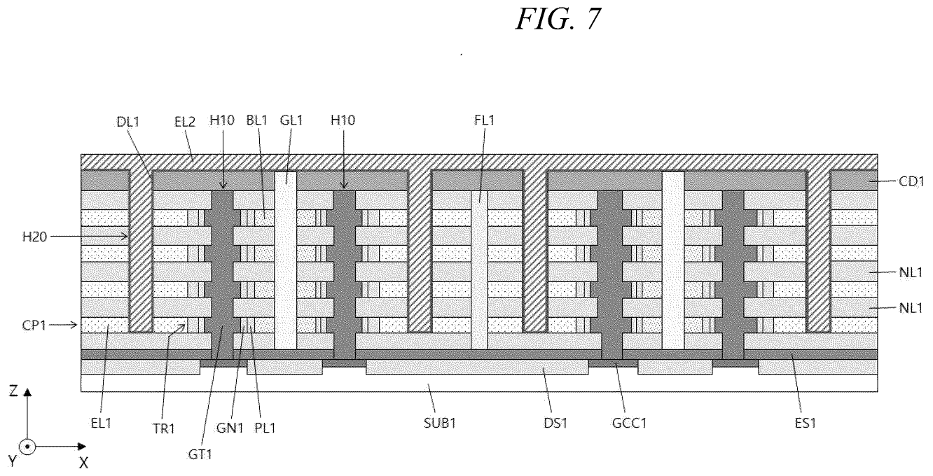

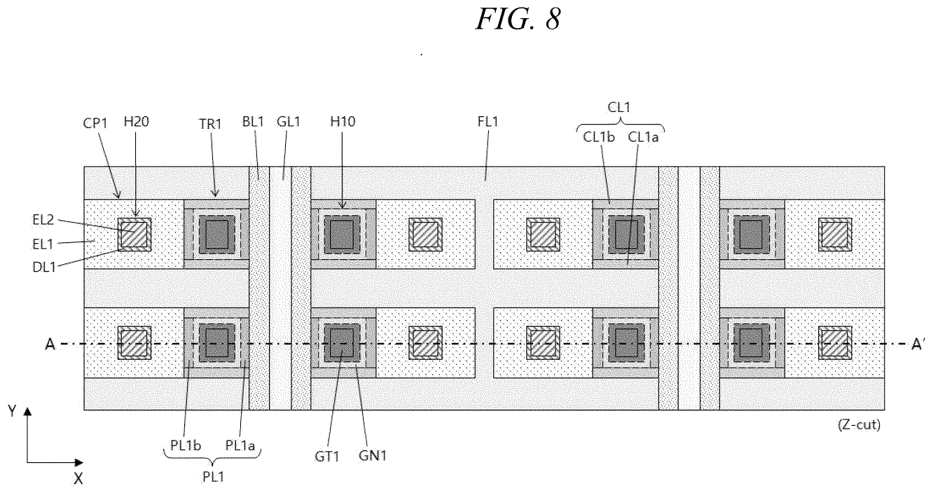

FIG. 7 and FIG. 8 are cross-sectional diagrams illustrating a three-dimensional memory device according to an embodiment of the present disclosure. FIG. 7 is a cross-sectional diagram cut along the XZ plane, and FIG. 8 is a cross-sectional diagram cut along the XY plane. FIG. 7 may be a cross-sectional diagram taken along line A-A′ of FIG. 8.

Referring to FIGS. 7 and 8, the three-dimensional memory device may include a plurality of memory cells stacked in a vertical direction on a substrate SUB1. The vertical direction may be perpendicular to a top surface of the substrate SUB1. Each of the plurality of memory cells may include a transistor TR1 and a capacitor CP1 connected to the transistor TR1. The plurality of memory cells may be stacked with an insulating layer NL1 interposed between two adjacent memory cells in the vertical direction. The insulating layer NL1 may be disposed between a plurality of transistors TR1 and between a plurality of capacitors CP1.

A plurality of device isolation films DS1 may be formed on the substrate SUB1, and a gate connection layer GCC1 having a predetermined pattern structure may be disposed between two adjacent device isolation films among the plurality of device isolation films DS1 in a horizontal direction that is parallel to the top surface of the substrate SBU1. An etching stop layer ES1 may be formed on the substrate SUB1 to cover the device isolation film DS1 and the gate connection layer GCC1. The substrate SUB1 may be a semiconductor substrate. For example, the substrate SUB1 may be one of a silicon substrate, a silicon-germanium substrate, and a germanium substrate, or may be a substrate including a single crystal epitaxial layer grown on a single crystal substrate. The substrate SUB1 may include a conductive region, for example, a well doped with impurities or an active region. The device isolation film DS1 may be an insulating film. The gate connection layer GCC1 is electrically connected to a gate GT1, and may be formed through high concentration doping. For example, the etching stop layer ES1 may be formed of aluminum oxide or silicon nitride.

The plurality of transistors TR1 may be stacked on the substrate SUB1 or the gate connection layer GCC1 with the insulating layers NL1 interposed therebetween. Similarly, the plurality of capacitors CP1 may be stacked on the substrate SUB1 or the etching stop layer ES1 with the insulating layers NL1 interposed therebetween. One transistor TR1 may be electrically connected to one capacitor CP1 disposed at the same level in the vertical direction. One transistor TR1 and one capacitor CP1 connected to it constitute one memory cell. The insulating layer NL1 may include one or more of various insulating materials such as silicon oxide, silicon nitride, silicon oxynitride, low-k materials, and high-k materials.

The transistor TR1 may include a polycrystalline layer PL1 with vertically oriented crystal grains, a channel layer CL1 in contact with a side surface of the polycrystalline layer PL1 and having a structure with vertically oriented crystal grains, a source and a drain provided on (in) first and second portions of the channel layer CL1, respectively, and a gate GT1 for controlling the electrical characteristic of the channel layer CL1. A first vertical hole H10 may be formed in a transistor formation region, and the gate GT1 may be formed within the first vertical hole H10. The transistor TR1 may further include a gate insulating layer GN1 formed surrounding the gate GT1, and the polycrystalline layer PL1 and the channel layer CL1 may be disposed to contact the gate insulating layer GN1. The gate GT1 may have a pillar shape shared by the plurality of transistors TR1. The gate GT1 may constitute a word line connected to the plurality of transistors TR1.

The capacitor CP1 may include a first electrode EL1 disposed at the same level as each transistor TR1 in the vertical direction. Furthermore, the capacitor CP1 may further include a dielectric layer DL1 and a second electrode EL2. A second vertical hole H20 may be formed in a capacitor formation region, and the dielectric layer DL1 in contact with the first electrode EL1 may be formed on an inner surface of the second vertical hole H20, and the second electrode EL2 may be formed on the dielectric layer DL1 to fill the remaining portion of the second vertical hole H20 after the dielectric layer DL1 is formed. The second electrode EL2 may be commonly applied to the plurality of capacitors CP1 as a common electrode. The second electrode EL2 may be referred to as a type of plate electrode.

Furthermore, a plurality of bit lines BL1 respectively connected to the plurality of memory cells and extending in the horizontal direction may be further provided. The plurality of bit lines BL1 may be arranged to be connected to the plurality of transistors TR1, respectively. Each of the bit lines BL1 may be arranged to contact a corresponding one of the transistors TR1 at the same level in the vertical direction. Accordingly, the insulating layer NL1 may be disposed between the plurality of bit lines BL1 in the vertical direction.

A source and a drain may be provided on (in) the first portion and the second portion of the channel layer CL1 of the transistors TR1, respectively. For example, one of the bit line BL1 and the first electrode EL1 of the capacitor CP1 may be the source, and the other may be the drain. Alternatively, a first end of the channel layer CL1 in contact with the bit line BL1 may be the source (or drain), and a second end of the channel layer CL1 in contact with the first electrode EL1 may be the drain (or source).

In the channel length direction, the polycrystalline layer PL1 may have a discontinuous structure between the source and the drain, and the channel layer CL1 may have a continuous structure between the source and the drain. The grain boundaries of the channel layer CL1 may be arranged in a direction non-parallel to the channel length direction between the source and the drain. These features may be the same as those described in detail with reference to FIGS. 1 and 3.

According to one embodiment, the polycrystalline layer PL1 and the channel layer CL1 may have a columnar crystal grain structure. The channel layer CL1 may include a first channel layer CL1a in contact with a first side surface of the polycrystalline layer PL1 and a second channel layer CL1b in contact with a second side surface of the polycrystalline layer PL1. Here, each of the first channel layer CL1a and the second channel layer CL1b may have a continuous structure in the channel length direction between the source and the drain. Furthermore, the polycrystalline layer PL1 may include a first polycrystalline layer portion PL1a adjacent to the source and a second polycrystalline layer portion PL1b adjacent to the drain. The first polycrystalline layer portion PL1a and the second polycrystalline layer portion PL1b may be arranged to be spaced apart from each other in the channel length direction between the source and the drain. For example, in the horizontal direction, the grain boundaries of the channel layer CL1 may be arranged in a direction perpendicular to the channel length direction. In addition, the transistor TR1 may have all of the characteristics described above with reference to FIGS. 1 and 3.

In FIGS. 7 and 8, a filling insulating layer FL1 may be disposed between memory cell regions, and a separation insulating layer GL1 may be formed to separate memory cell regions between bit lines BL1, and a top insulating material layer (or a capping insulating material layer) CD1 may be formed to cover the stack structures.

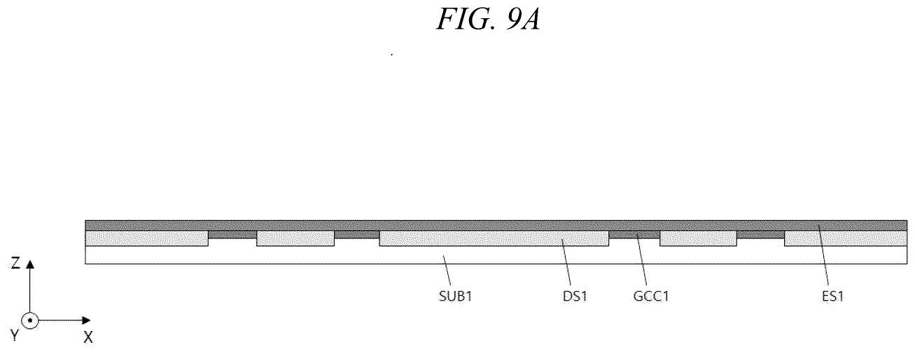

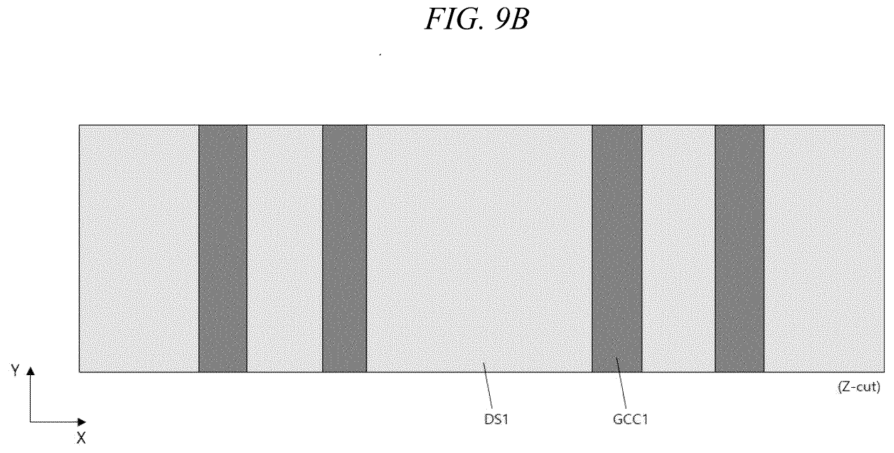

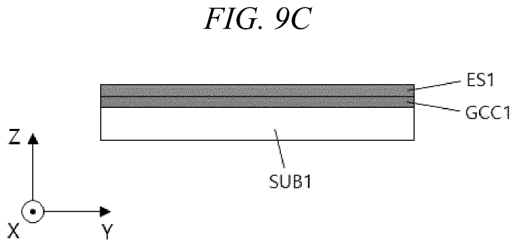

FIG. 9A to FIG. 23B are diagrams for explaining a manufacturing method of a three-dimensional memory device according to an embodiment of the present disclosure.

FIGS. 9A, 10A, 11A, 12A, 13A, 14A, 15A, 16A, 17A, 18A, 19A, 20A, 21A, 22A, and 23A are cross-sectional diagrams cut in the XZ plane. FIGS. 9B, 10B, 11B, 12B, 13B, 14B, 15B, 16B, 17B, 18B, 19B, 20B, 21B, 22B, and 23B are plan diagrams observed from the top (that is, a top-diagram) or a cross-sectional diagram cut along the XY plane (i.e., Z-cut diagram). FIGS. 9C, 10C, 11C, 12C, 13C, 14C, 15C, 16C, and 17C are cross-sectional diagrams cut in the YZ plane.

Referring to FIGS. 9A to 9C, a predetermined substrate structure may be prepared. The substrate structure may include a substrate SUB1, a device isolation layer DS1 formed on the substrate SUB1, a gate connection layer GCC1, and an etching stop layer ES1. The device isolation layer DS1 may include a plurality of device isolation films DS1 formed on the substrate SUB1, and the gate connection layer GCC1 may have a predetermined pattern structure including a plurality of patterns, each pattern being disposed between two films of the plurality of device isolation films DS1. The etching stop layer ES1 may be formed on the substrate SUB1 and cover the device isolation layer DS1 and the gate connection layer GCC1. FIG. 9B shows the planar structure of the device isolation layer DS1 and the gate connection layer GCC1. FIG. 9C is an YZ cross-sectional diagram of a portion where the gate connection layer GCC1 is formed. However, the specific configuration of the substrate structure shown in FIG. 9A to FIG. 9C is merely an example and may be modified in various ways.

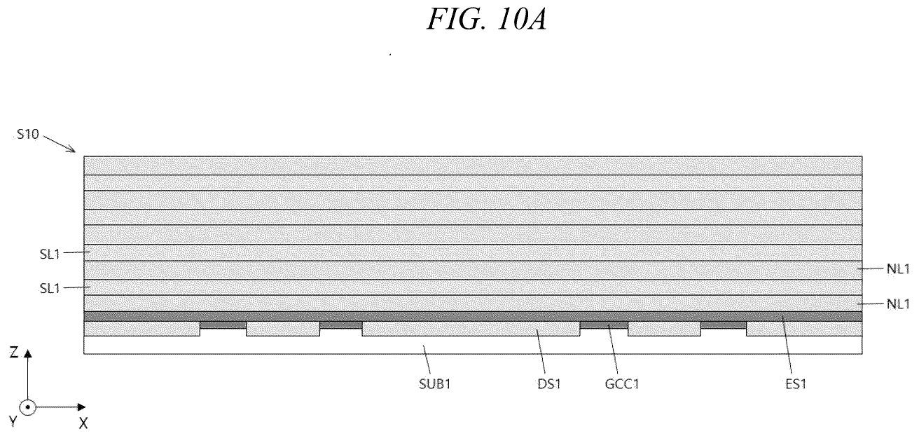

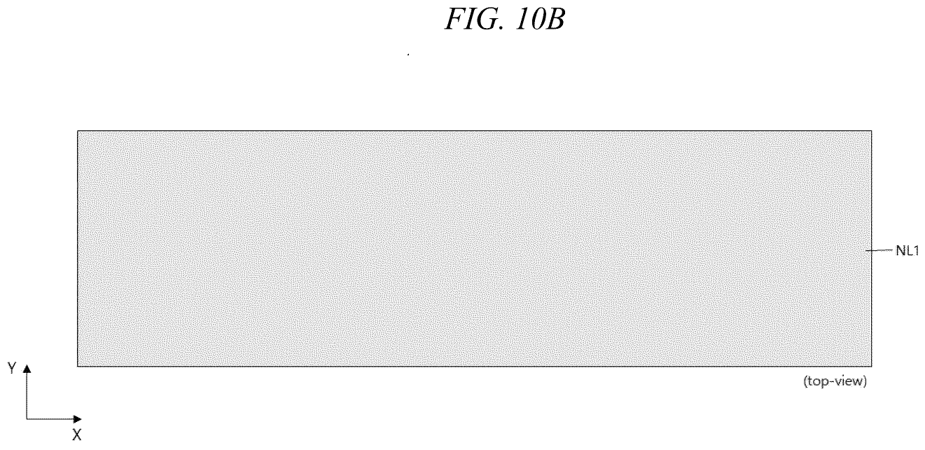

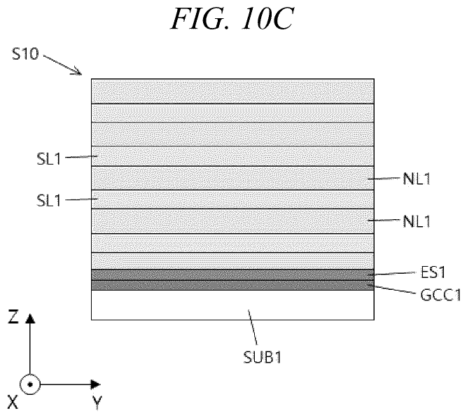

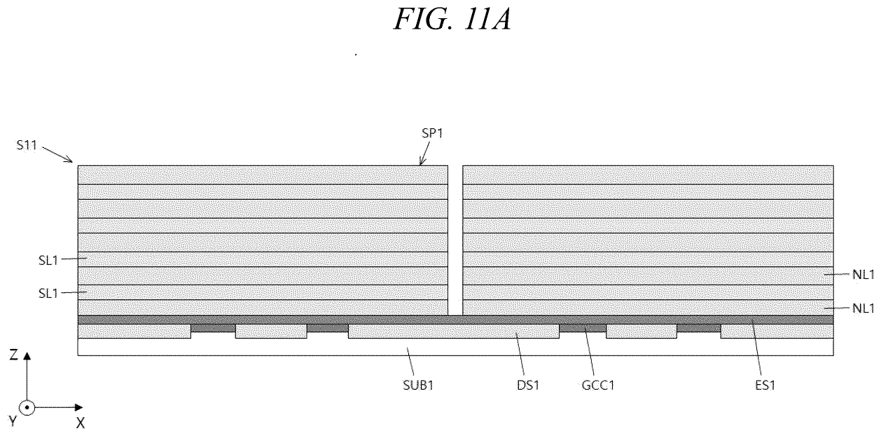

Referring to FIG. 10A to FIG. 10C, a stacked structure S10 may be formed where an insulating layer NL1 and a first semiconductor material layer SL1 are alternately and repeatedly stacked on the etching stop layer ES1. The insulating layer NL1 and the first semiconductor material layer SL1 may be deposited and stacked by using a chemical vapor deposition (CVD) method. For example, the first semiconductor material layer SL1 may include any one of Si, Ge, and SiGe. The first semiconductor material layer SL1 may initially have an amorphous or polycrystalline structure. Subsequently, by heat-treating the first semiconductor material layer SL1, crystal grains may be grown and vertically oriented within the first semiconductor material layer SL1. For example, the heat-treatment of the first semiconductor material layer SL1 may be performed at a temperature of about 800° C. or higher. The crystal grains may be grown and vertically oriented within the first semiconductor material layer SL1 through the heat-treatment. After the heat-treatment, the first semiconductor material layer SL1 may have a structure with vertically oriented crystal grains. For example, the first semiconductor material layer SL1 may have a columnar crystal grain structure. After the heat-treatment, the first semiconductor material layer SL1 may be converted into a polycrystalline layer with vertically oriented crystal grains.

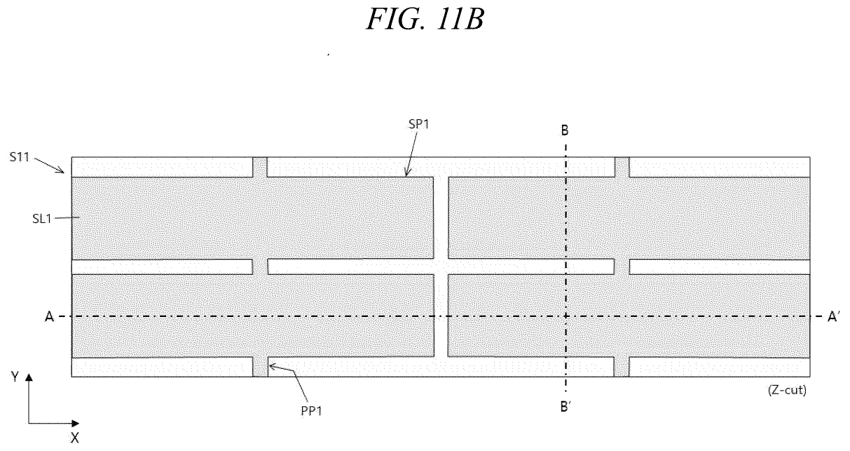

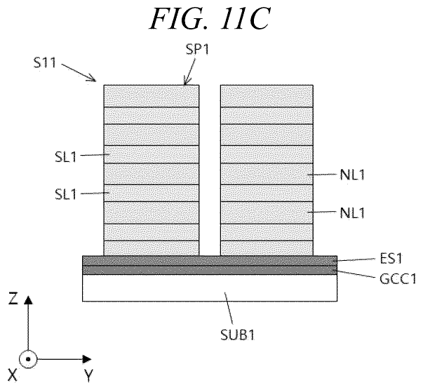

Referring to FIG. 11A to FIG. 11C, a cell patterning process may be performed on the stacked structure S10 to form a patterned stack structure S11 including a stack structure pattern SP1. The stack structure pattern SP1 may have a rectangular shape when observed from a top side. A plurality of stacked structure patterns SP1 may be arranged to form a plurality of rows and a plurality of columns in the X-axis direction and the Y-axis direction. Furthermore, connection pattern portions PP1, which are shown in FIG. 11B and connect the plurality of stacked structure patterns SP1 in the Y-axis direction, may be formed. However, the shape of the patterned stack structure S11 is illustrative and may vary in different ways. Side surfaces of the first semiconductor material layer SL1 and the insulating layer NL1 may be exposed from side surfaces of the stack structure pattern SP1 through etching during the cell patterning process.

FIG. 11A is a cross-sectional diagram taken along line A-A′ of FIG. 11B, and FIG. 11C is a cross-sectional diagram taken along line B-B′ of FIG. 11B. This relationship may be approximately equally applied in the following drawings.

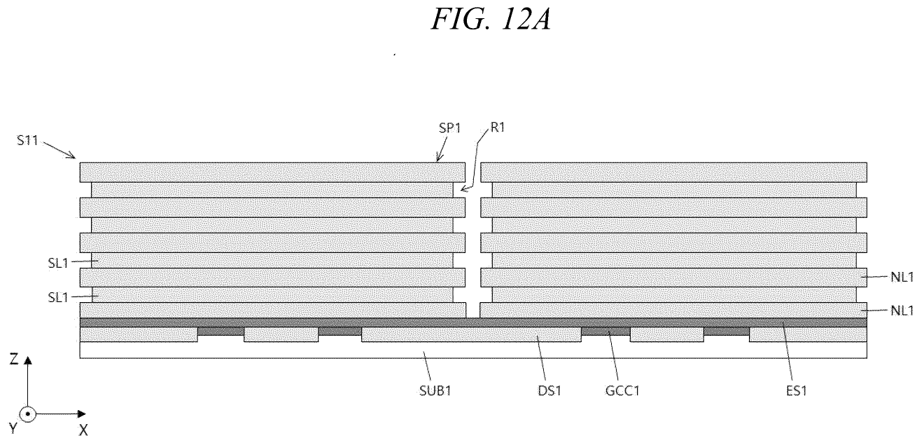

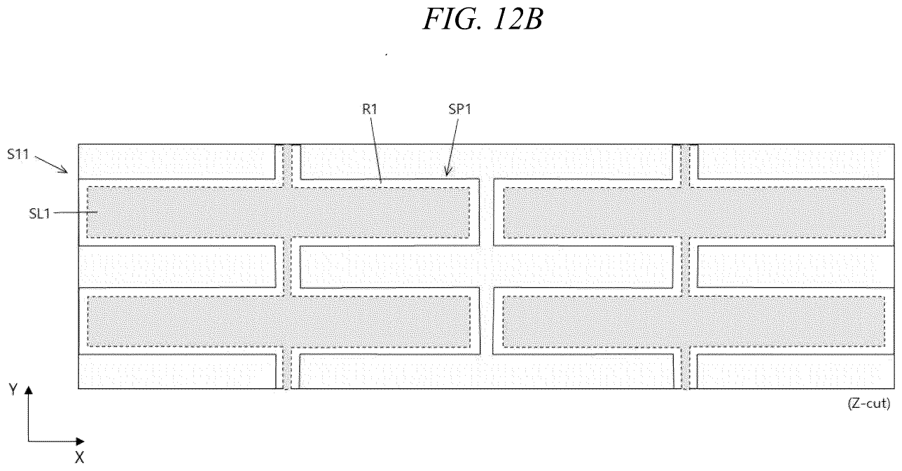

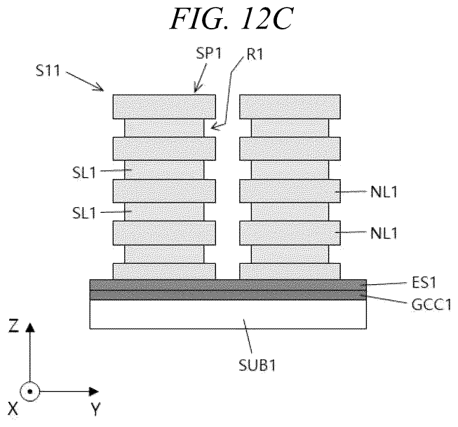

Referring to FIG. 12A to FIG. 12C, a first recess region R1 may be formed by recessing the first semiconductor material layer SL1 in the stack structure pattern SP1. Isotropic etching may be performed on the first semiconductor material layer SL1 through the opening around the stack structure pattern SP1 to recess the first semiconductor material layer SL1 to a certain depth in the horizontal direction. At this time, the insulating layer NL1 may remain unetched or only minimally etched. The isotropic etching may be performed by wet etching or dry etching. In the recess process, for example, a wet etching method based on ammonia water or TMAH (tetra-methyl ammonium hydroxide) may be used. For example, the recess process may be performed using a wet etching method under conditions where TMAH is diluted with isopropyl alcohol (IPA), with the chemical temperature kept at 50° C. or lower, and an etching rate is maintained at 20 nm or less per minute.

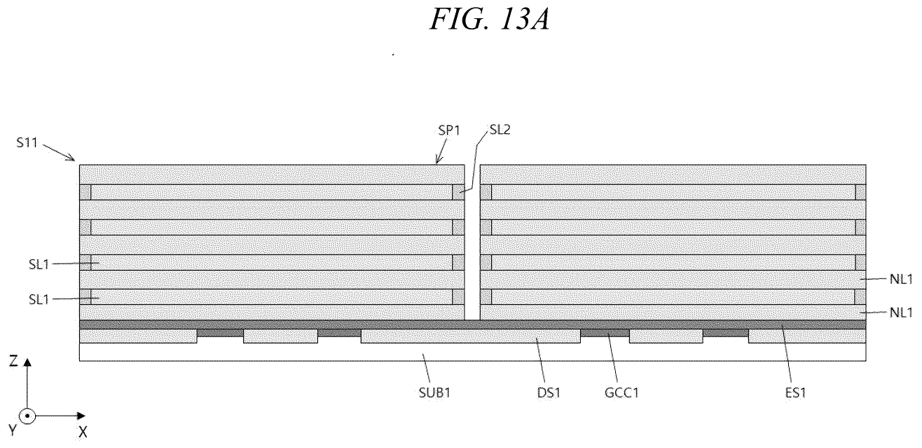

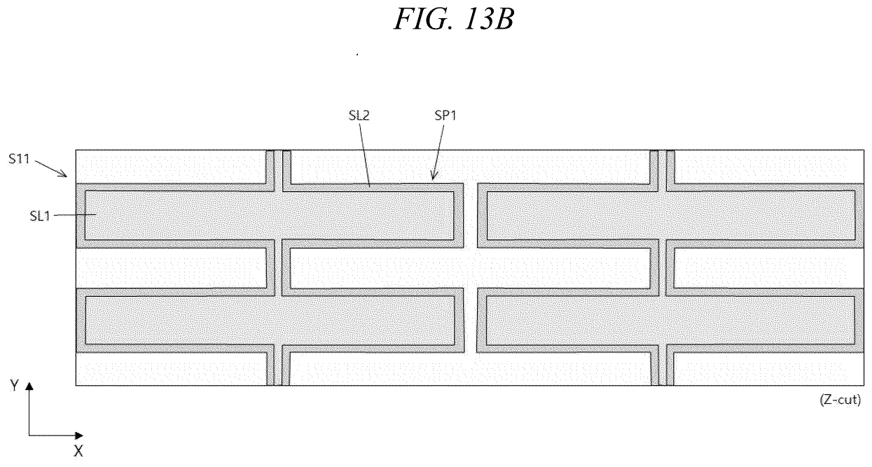

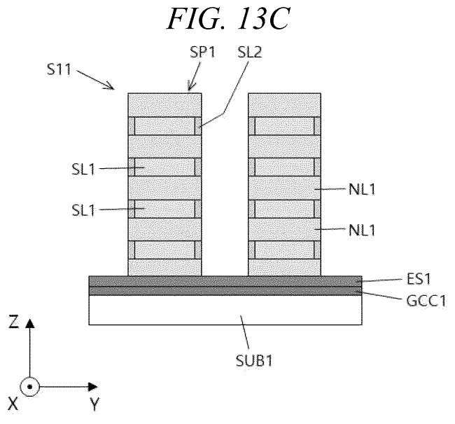

Referring to FIG. 13A to FIG. 13C, a second semiconductor material layer SL2, with vertically oriented crystal grains, may be formed using an epitaxial process from a side surface of the first semiconductor material layer SL1 in the first recess region R1. During the formation of the second semiconductor material layer SL2, the vertically oriented grains may be maintained without generating additional grain boundaries by conducting selective epitaxial growth in the horizontal direction while using the vertically oriented crystal grains of the first semiconductor material layer SL1 as seeds. For example, the second semiconductor material layer SL2 may include any one of Si, Ge, and SiGe.

If an epitaxial material grows on the surface of some of the insulating layers NL1, it can be removed through an additional etching process. Accordingly, the second semiconductor material layer SL2 may be confined exclusively within the first recess region R1.

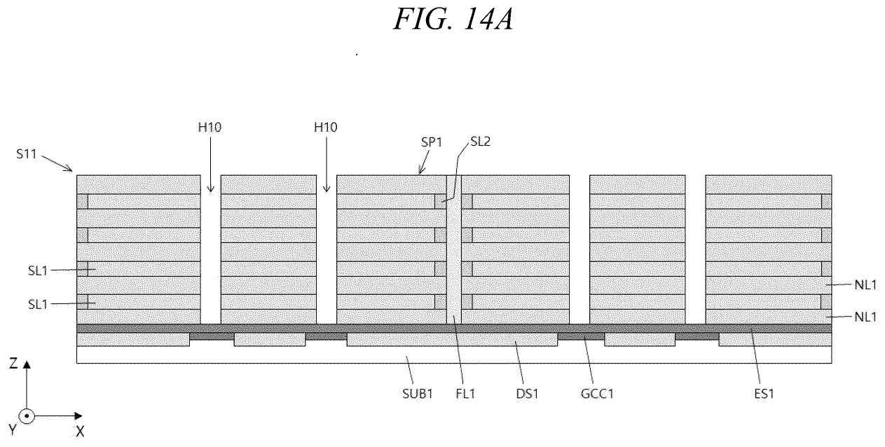

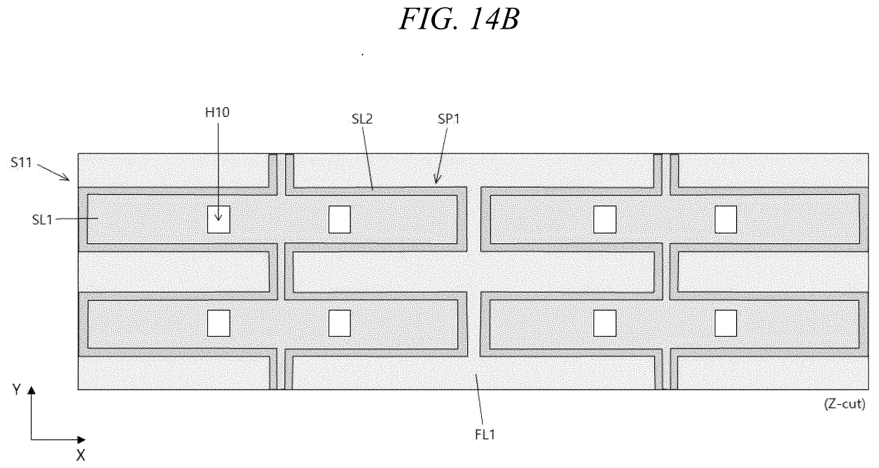

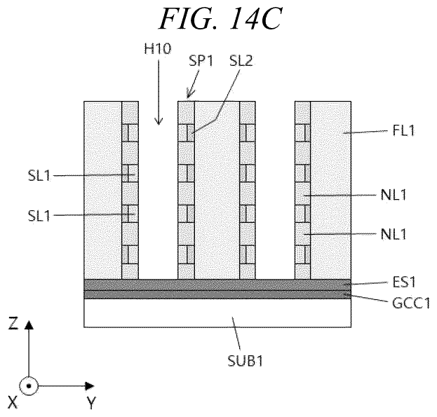

Referring to FIG. 14A to FIG. 14C, a filling insulating layer FL1 may be formed to fill the empty space around the patterned stack structure S11, where the second semiconductor material layer SL2 is formed. Subsequently, planarization may be performed if necessary. Then, a first vertical hole H10 may be formed in a transistor formation region where transistors are intended to be formed within the stack structure pattern SP1. The first vertical hole H10 may be formed to penetrate through the stack structure pattern SP1 in the vertical direction. The first vertical hole H10 may be referred to as a ‘transistor hole.’ The first vertical hole H10 may serve as a contact hole, intended for the subsequent formation of a gate structure. The width of the first vertical hole H10 in the Y-axis direction may be equal to or smaller than the width of the first semiconductor material layer SL1 of the stack structure pattern SP1 in the Y-axis direction. A plurality of first vertical holes H10 may be formed as illustrated. The plurality of first vertical holes H10 may be formed over the gate connection layer GCC1.

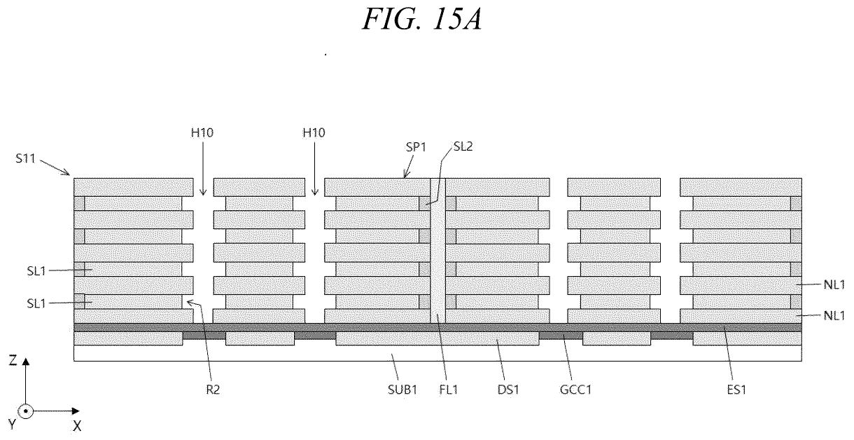

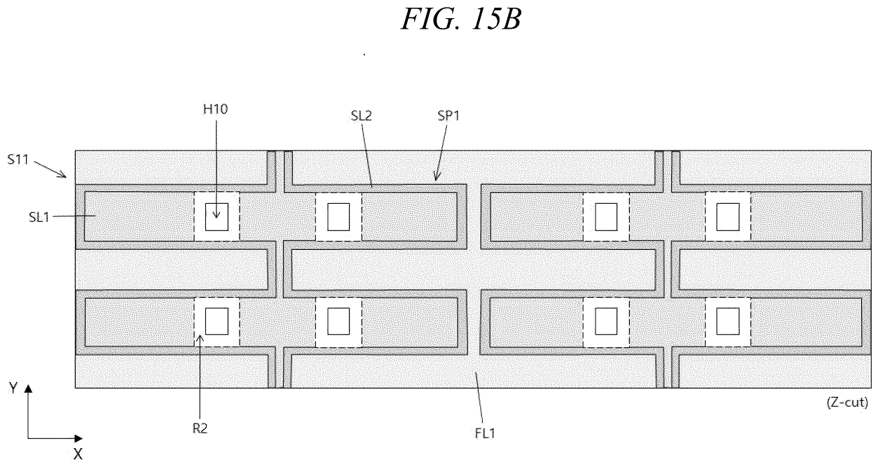

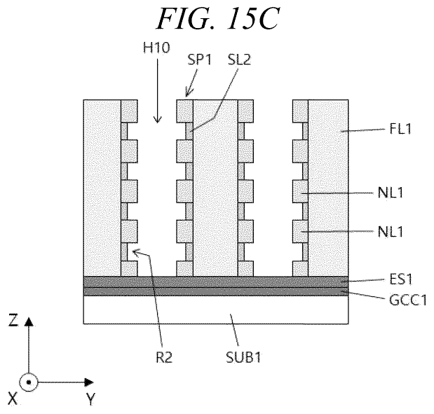

Referring to FIG. 15A to FIG. 15C, a second recess region R2 may be formed by recessing the exposed portion of the first semiconductor material layer SL1, which is exposed by the first vertical hole H10. The recess for the first semiconductor material layer SL1 may be performed in the horizontal direction, encompassing both the X-axis and Y-axis directions. The first semiconductor material layer SL1 may be recessed until a side surface of the second semiconductor material layer SL2 is exposed in the Y-axis direction. Accordingly, the side surface of the second semiconductor material layer SL2 may be exposed in the Y-axis direction by the second recess region R2. In this recess process, for example, a wet etching method based on ammonia water or TMAH may be used. Alternatively, in the step depicted in FIG. 14A, the side surface of the second semiconductor material layer SL2 may be exposed by forming the first vertical hole H10 with a large size, thereby removing all of the first semiconductor material layer SL1 in the Y-axis direction. In this case, the recess process described in FIG. 15A to FIG. 15C may not be necessary.

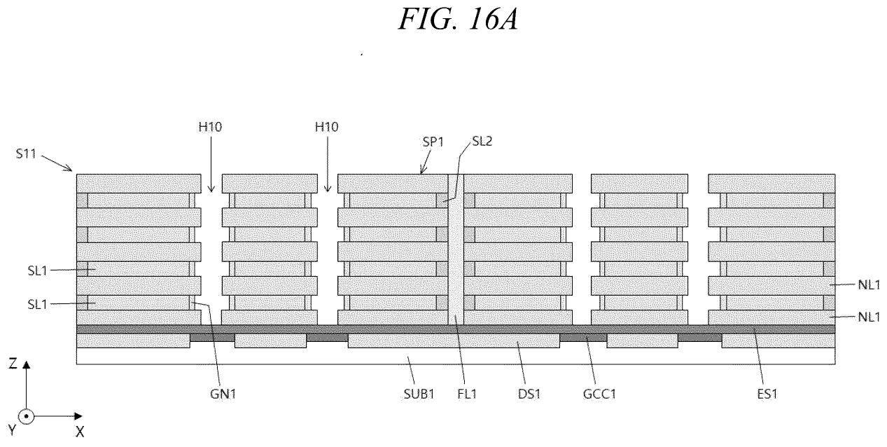

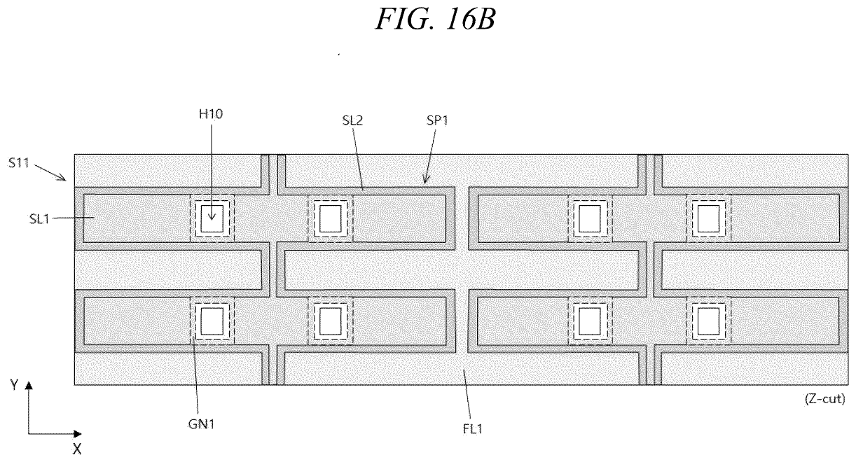

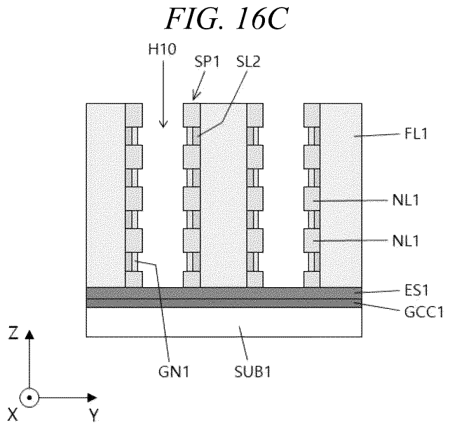

Referring to FIG. 16A to FIG. 16C, a gate insulating layer GN1 may be formed in the second recess region R2. The gate insulating layer GN1 may be formed using a deposition method. The gate insulating layer GN1 may include at least one of silicon oxide, silicon nitride, silicon oxynitride, or a high-k material having insulating properties. The high-k material may be a material with a higher dielectric constant than silicon nitride. Examples may include, but are not limited thereto, aluminum oxide, hafnium oxide, and similar materials. Even when the first semiconductor material layer SL1 is not additionally recessed, the gate insulating layer GN1 may be formed (or deposited) on the side surface of the second semiconductor material layer SL2 exposed through the expanded first vertical hole H10.

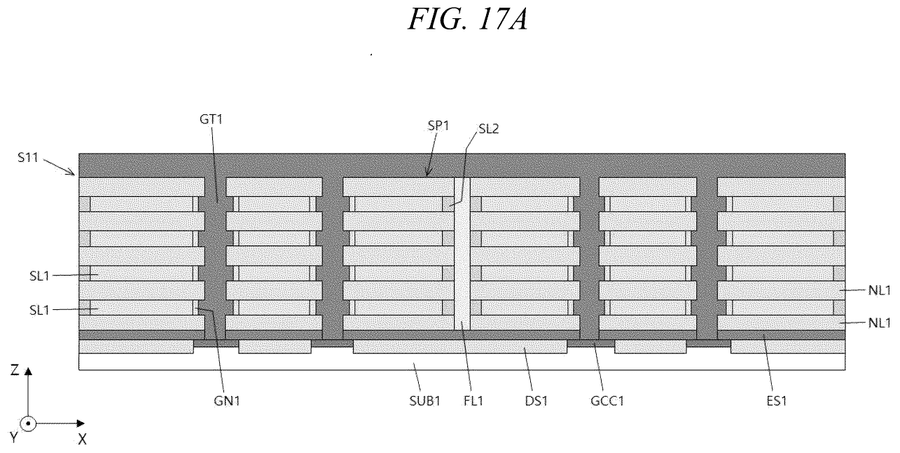

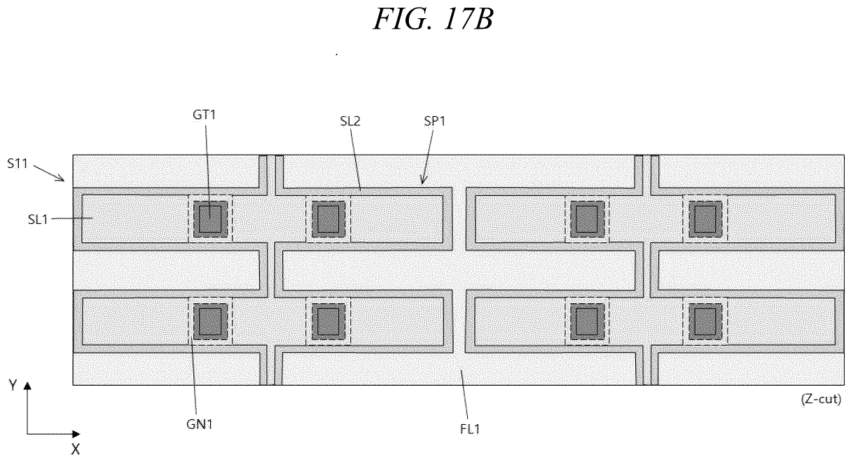

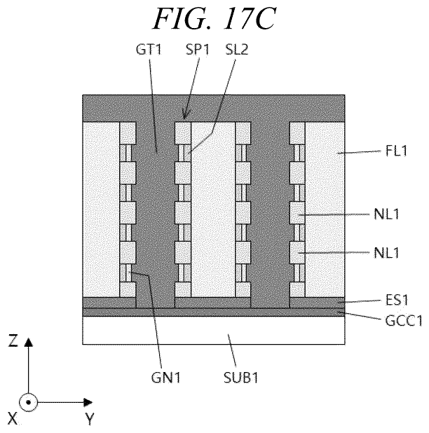

Referring to FIG. 17A to FIG. 17C, the gate connection layer GCC1 may be exposed by etching the etching stop layer ES1 that has been exposed by forming the first vertical hole H10, and then a gate GT1 may be formed to fill the remaining portion of the first vertical hole H10 after the gate insulating layer GN1 is formed. The gate GT1 may be formed on the gate insulating layer GN1 and may be formed to fill the first vertical hole H10. The gate GT1 may be formed to be connected with (or contact) the gate connection layer GCC1. The gate GT1 may be formed from a doped semiconductor material (e.g., doped polysilicon) or a metallic conductive material. For example, the metallic conductive material may include any one selected from the group consisting of tungsten (W), copper (Cu), aluminum (Al), titanium (Ti), tantalum (Ta), molybdenum (Mo), ruthenium (Ru), gold (Au), titanium nitride (TiN), tantalum nitride (TaN), and the like. However, the material of the gate GT1 is not limited to the above materials and may vary in different ways. The material for forming the gate GT1, that is, a gate constituting material, may also be deposited on an upper surface of the patterned stack structure S11. The gate constituting material deposited on the upper surface of the patterned stack structure S11 may be removed through an etch-back process or a planarization process.

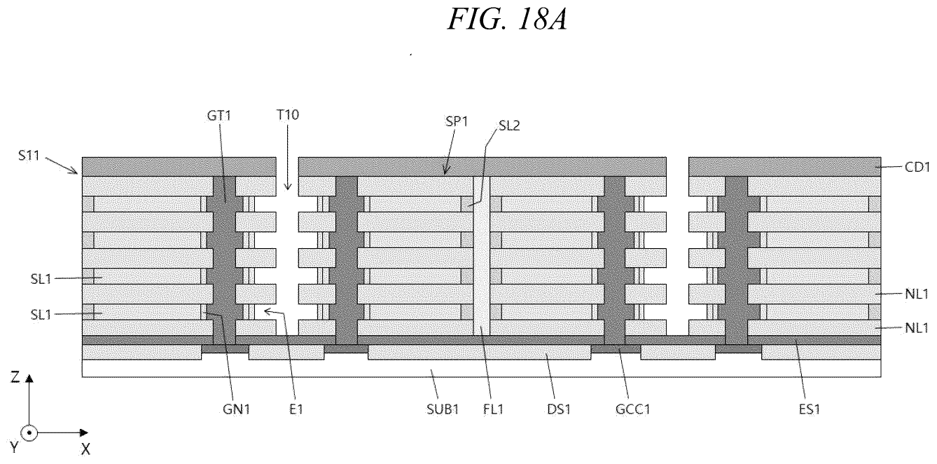

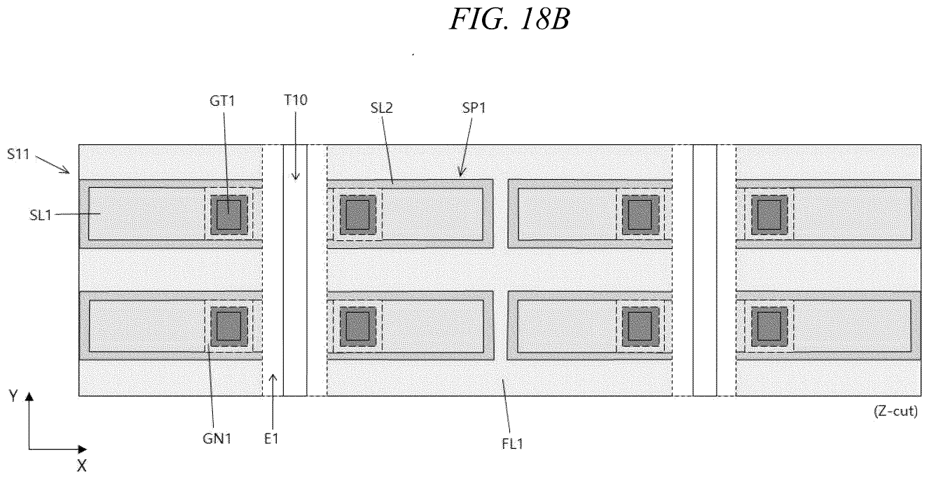

Referring to FIG. 18A and FIG. 18B, an upper insulating material layer CD1 may be formed on the upper surface of the patterned stack structure S11 and the filling insulating layer FL1. That is, the upper insulating material layer CD1 may be formed to cover the resulting structure of FIGS. 17A to 17C after the gate constituting material deposited on the upper surface of the patterned stack structure S11 is removed. The upper insulating material layer CD1 may be formed of any of various insulating materials. Subsequently, an opening T10 may be formed in a region of the stack structure pattern SP1 adjacent to the transistor formation region. The opening T10 may be a type of etched portion. For example, the opening T10 may have a line shape parallel to the Y-axis direction. In addition, the opening T10 may be formed to penetrate through the stack structure pattern SP1 in the Z-axis direction and have a trench shape. The opening T10 may extend through the stack structure pattern SP1 until the etching stop layer ES1 is exposed.

Then, portions of the first and second semiconductor material layers SL1 and SL2 exposed by the opening T10 may be etched (or recessed) to form a first etched region E1. The first etched region E1 may be a type of recess region. By using the etch selectivity, the portions of the first and second semiconductor material layers SL1 and SL2 may be recessed with minimal or no etching of the insulating layer NL1.

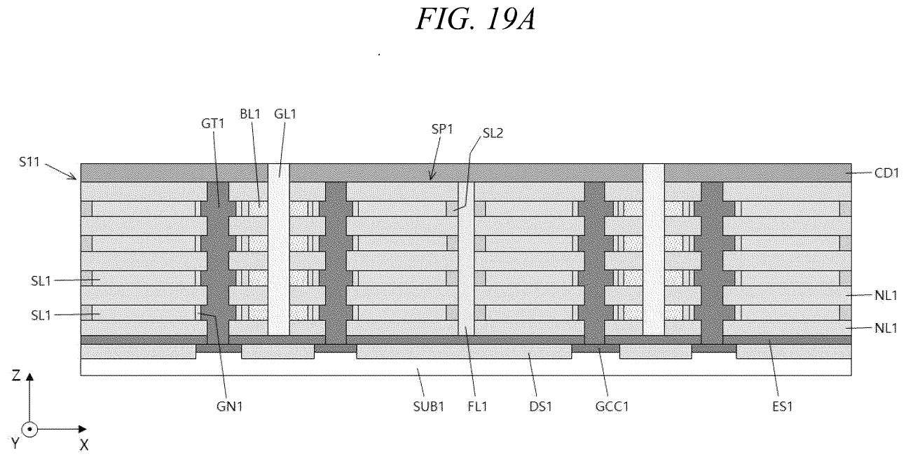

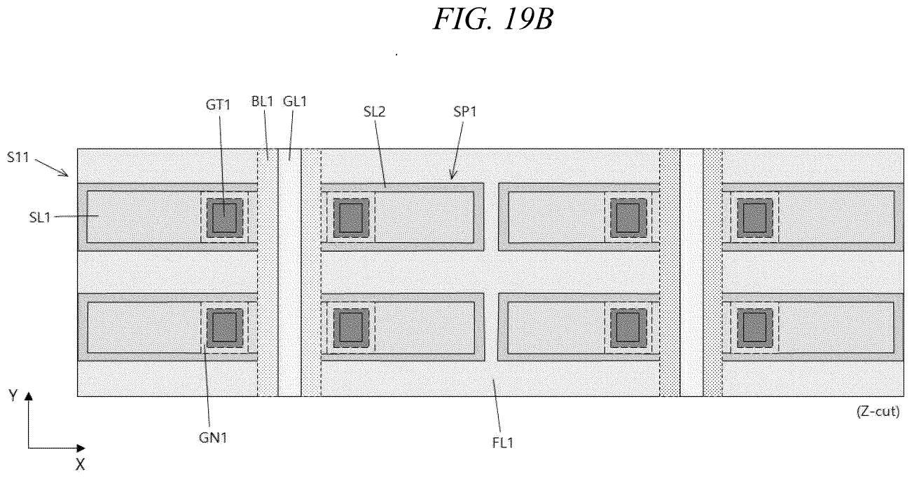

Referring to FIG. 19A and FIG. 19B, a bit line BL1 may be formed in the first etched region E1. A conductive material for a bit line may be deposited in the opening T10 and the first etched region E1. The conductive material for the bit line in the opening T10 may be removed by performing an anisotropic etching, leaving the conductive material only in the first etched region E1. After forming the bit line BL1, a separation insulating layer GL1 may be formed within the opening T10 where the conductive material for the bit line is removed. The separation insulating layer GL1 may serve to separate memory cell regions between the bit lines BL1.

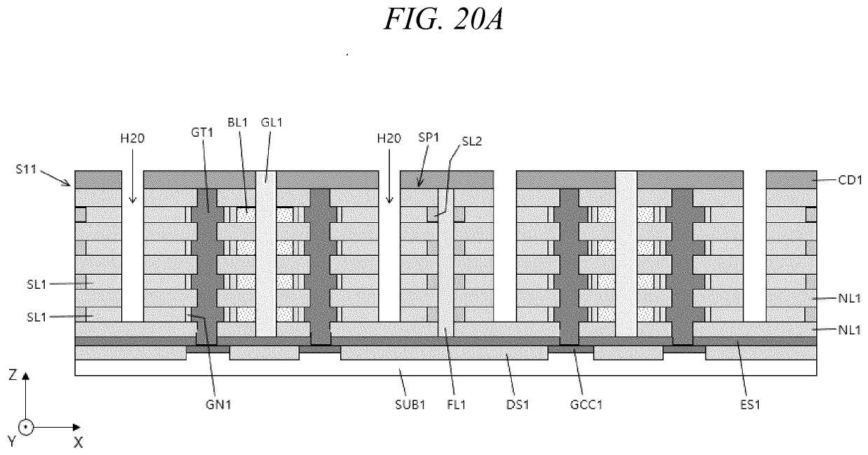

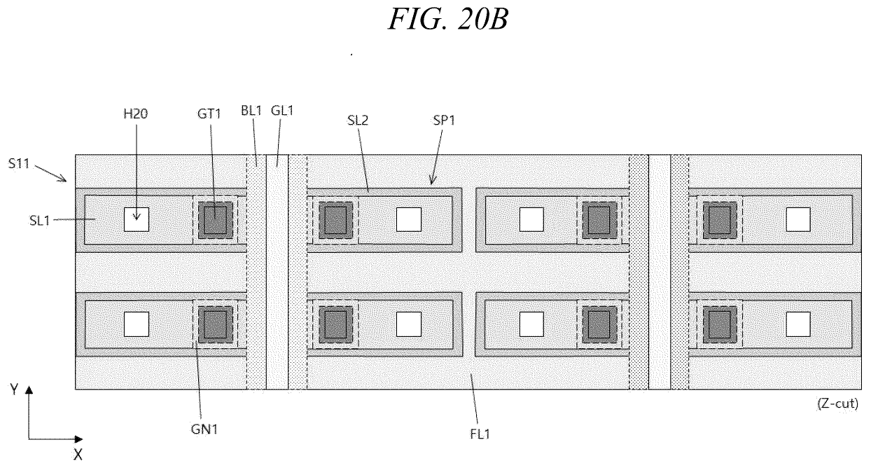

Referring to FIG. 20A and FIG. 20B, a second vertical hole H20 may be formed in a capacitor formation region, which is a region designated for the formation of a capacitor, within the stack structure pattern SP1. The second vertical hole H20 may be formed using a well-known lithography process. The second vertical hole H20 may be formed to penetrate through the stack structure pattern SP1. Alternatively, when forming the second vertical hole H20, the lowest layer portion of the stacked structure pattern SP1 may not be etched. The second vertical hole H20 may be formed to correspond 1:1 with the transistor formation region and be positioned beside the corresponding transistor formation region. The second vertical hole H20 may be referred to as a ‘capacitor hole.’

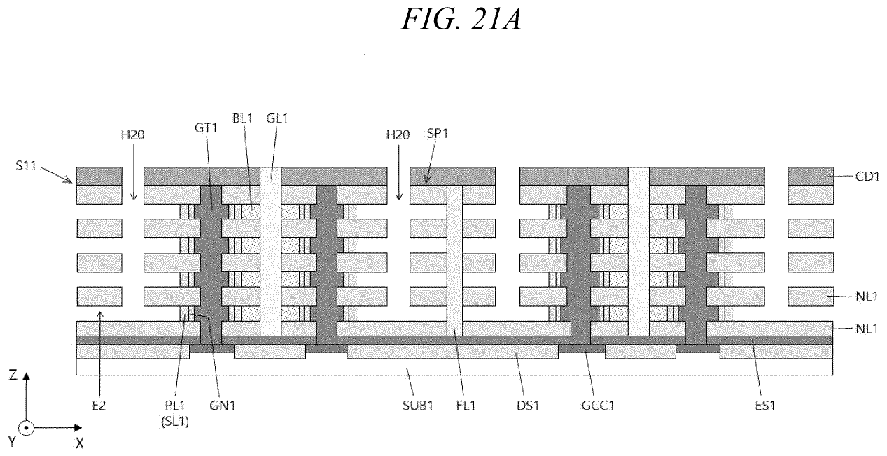

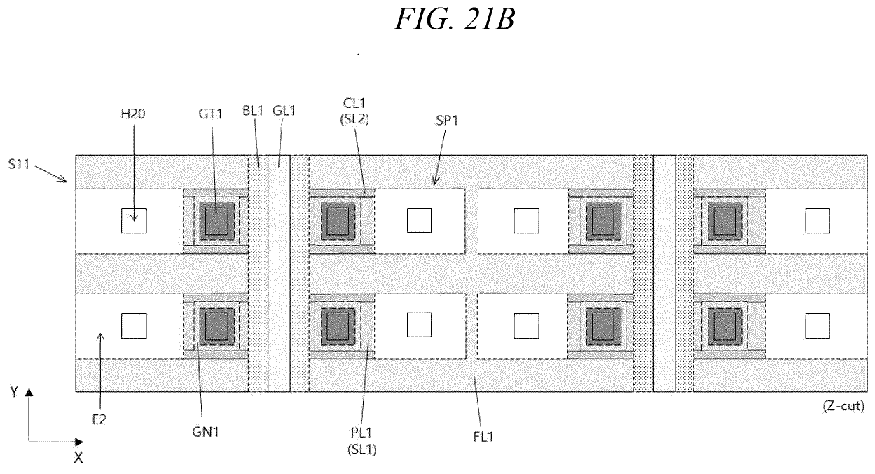

Referring to FIG. 21A and FIG. 21B, a second etched region E2 may be formed by recessing the first semiconductor material layer SL1 and the second semiconductor material layer SL2 exposed by the second vertical hole H20. In the transistor formation region, a polycrystalline layer PL1 patterned from the first semiconductor material layer SL1 may be defined, and a channel layer CL1 patterned from the second semiconductor material layer SL2 may be defined. The polycrystalline layer PL1 and the channel layer CL1 may have the same structure as described in FIG. 7 and FIG. 8. The second etched region E2 may be a type of recess region. By using the etching selectivity, portions of the first and second semiconductor material layers SL1 and SL2 may be recessed without etching the insulating layer NL1, or while barely etching the insulating layer NL1.

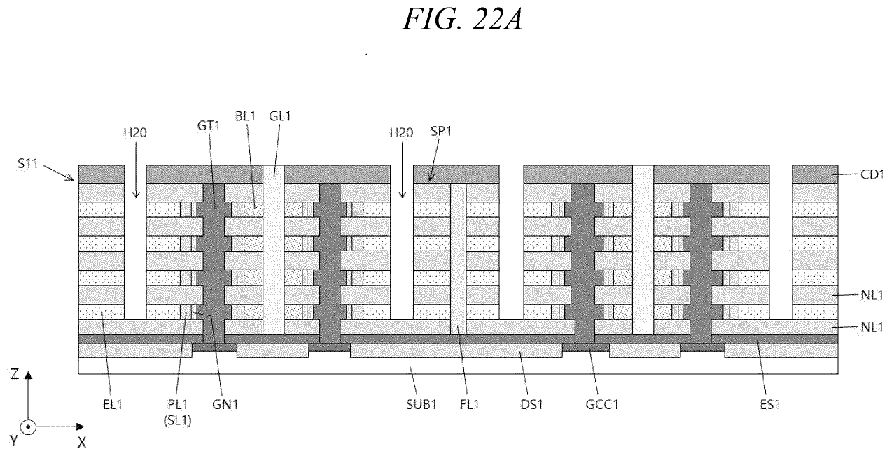

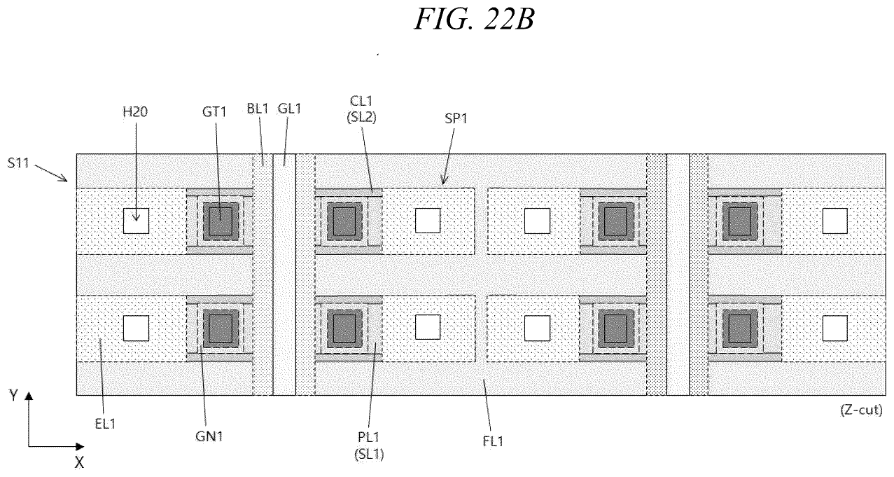

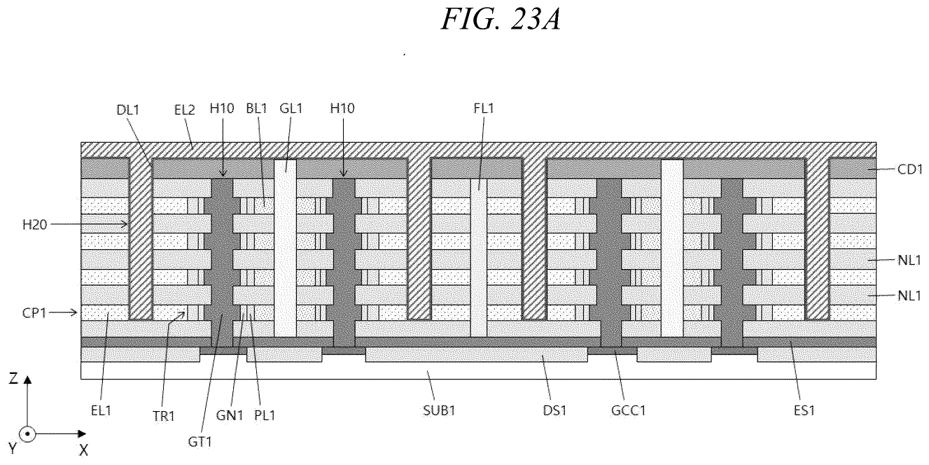

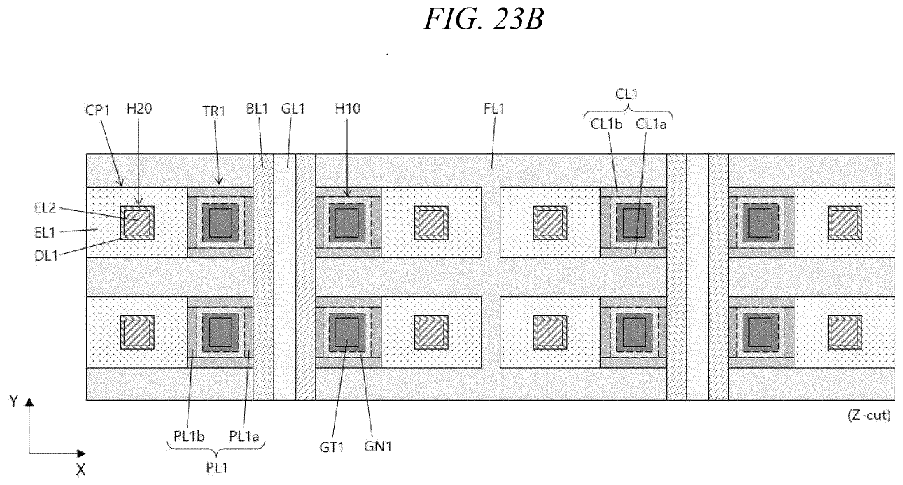

Referring to FIG. 22A to FIG. 23B, a capacitor structure may be formed in the second etched region E2 and the second vertical hole H20. The step for forming the capacitor structure may include a step for forming a first electrode EL1 in the second etched region E2, a step for forming a dielectric layer DL1 in the second vertical hole H20, and a step for forming a second electrode EL2 filling the second vertical hole H20 after the dielectric layer DL1 is formed. In the step for forming the first electrode EL1, after depositing a first electrode material in the second etched region E2 and the second vertical hole H20, first electrodes EL1 for memory cells can be separated from each other by creating the second vertical hole H20 again through anisotropic etching on the first electrode material. In the step for forming the dielectric layer DL1 in the second vertical hole H20, the dielectric layer DL1 is deposited along a profile of the resulting structure after creating the second vertical hole H20 again through the anisotropic etching. The capacitor structure may include a plurality of capacitors CP1.

Referring to FIG. 23B, a source and a drain may be provided on (in) a first portion and a second portion of the channel layer CL1 of the transistor TR1, respectively. For example, one of the bit line BL1 and the first electrode EL1 may be a source, and the other may be a drain. Alternatively, a first end of the channel layer CL1 in contact with the bit line BL1 may be the source (or drain), and a second end of the channel layer CL1 in contact with the first electrode EL1 may be the drain (or source). The polycrystalline layer PL1 may have a discontinuous structure between the source and the drain, and the channel layer CL1 may have a continuous structure between the source and the drain. The grain boundaries of the channel layer CL1 may be arranged in a direction non-parallel to the channel length direction between the source and the drain.

According to one embodiment, each of the polycrystalline layer PL1 and the channel layer CL1 may have a columnar crystal grain structure. The channel layer CL1 may include a first channel layer CL1a in contact with a first side surface of the polycrystalline layer PL1 and a second channel layer CL1b in contact with a second side surface of the polycrystalline layer PL1. Here, each of the first and the second channel layers CL1a and CL1b may have a continuous structure between the source and the drain. Furthermore, the polycrystalline layer PL1 may include a first polycrystalline layer portion PL1a adjacent to the source and a second polycrystalline layer portion PL1b adjacent to the drain. The first and second polycrystalline layer portions PL1a and PL1b may be arranged to be spaced apart from each other in the channel length direction. For example, the grain boundaries of the channel layer CL1 may be arranged in a direction perpendicular to the channel length direction. In addition, the transistor TR1 may have all of the characteristics described with reference to FIGS. 1 and 3.

The structure of the three-dimensional memory device according to the embodiment is described in detail with reference to FIG. 7 and FIG. 8, and the manufacturing method of the three-dimensional memory device according to the embodiment is described in detail with reference to FIG. 9A to FIG. 23B. But, the structure and the manufacturing method of the three-dimensional memory device may vary in different ways. For example, the specific structure of the transistor and the specific structure of the capacitor connected to the transistor may vary in different ways.

According to the embodiments of the present disclosure, a memory device that exhibits excellent performance and operation characteristics while significantly enhancing integration may be easily implemented. According to the embodiments of the present disclosure, a memory device can be manufactured that lowers process difficulty, reduces manufacturing costs, and improves performance compared to the existing method using a Si/SiGe stack structure. This is achieved by manufacturing a three-dimensional memory device using a stack in which an insulating layer and a semiconductor material layer are alternately stacked. The memory device according to the embodiment of the present disclosure may be a three-dimensional DRAM device or a vertical DRAM device.

According to the embodiments of the present disclosure described above, it is possible to implement a semiconductor device and a three-dimensional memory device that can easily perform processes and improving productivity while increasing the degree of integration and ensuring excellent performance. In addition, according to the embodiments of the present disclosure, a semiconductor device and a three-dimensional memory device can be realized to improve device performance by suppressing leakage current and enhancing mobility, while ensuring ease of manufacturing and productivity. In particular, the off-current level can be significantly reduced by forming a channel layer with vertically oriented crystal grains and arranging the grain boundaries of the channel layer in a direction non-parallel to the channel length direction. Additionally, mobility characteristics can be enhanced by improving the crystallinity of the channel layer through a local epitaxy process.

In addition, according to the embodiments of the present disclosure, it is possible to manufacture a memory device that reduces process difficulty, improves the manufacturing process, and delivers enhanced performance compared to the existing method using a Si/SiGe stack structure. This is achieved by manufacturing a three-dimensional memory device using a stack in which an insulating layer and a semiconductor material layer are alternately stacked. For example, the three-dimensional memory device may include a three-dimensional dynamic random access memory (DRAM) device. However, at least some of the device structures and manufacturing methods according to the embodiments of the present disclosure may be applied not only to DRAM devices but also to other memory devices (e.g., PRAM, RRAM, SRAM, flash memory, MRAM, FRAM, etc.). They may also be applied to fields of technology that implement logic devices with integrated logic circuits.

In this specification, the preferred embodiments of the present disclosure have been disclosed, and although specific terms have been used, they are only used in a general sense to easily explain the technological content of the present invention and to help understanding the present invention, and they are not used to limit the scope of the present invention. It is obvious to those having ordinary skill in the related art to which the present invention belong that other modifications based on the technological idea of the present invention may be implemented in addition to the embodiments disclosed herein. It will be understood to those having ordinary skill in the related art that in connection with semiconductor devices, three-dimensional memory devices and manufacturing methods thereof according to the embodiments described with reference to FIG. 1A to FIG. 5F and FIG. 7 to FIG. 23B, various substitutions, changes, and modifications may be made without departing from the technological spirit of the present invention. Therefore, the scope of the invention should not be determined by the described embodiments, but should be determined by the technological concepts described in the claims.

What is claimed is:

1. A semiconductor device, comprising:
a transistor disposed over a substrate, the transistor comprising:
a polycrystalline layer in which crystal grains are vertically oriented;
a channel layer in contact with a side surface of the polycrystalline layer and having a structure in which crystal grains are vertically oriented;
a source and a drain provided on a first portion and a second portion of the channel layer, respectively; and
a gate configured to control an electrical characteristic of the channel layer,
wherein the polycrystalline layer has a non-connection type structure in a first direction between the source and the drain, the channel layer has a connection type structure in the first direction between the source and the drain, and grain boundaries of the channel layer are arranged in a second direction non-parallel to the first direction between the source and the drain, the first and the second directions being parallel to a top surface of the substrate.

2. The semiconductor device of claim 1, wherein the polycrystalline layer includes any one of Si, Ge, and SiGe, and the channel layer includes any one of Si, Ge, and SiGe.

3. The semiconductor device of claim 1, wherein the polycrystalline layer and the channel layer have a columnar crystal grain structure.

4. The semiconductor device of claim 1, wherein the channel layer is an epitaxially grown layer.

5. The semiconductor device of claim 1, wherein the channel layer includes a first channel layer in contact with a first side surface of the polycrystalline layer; and a second channel layer in contact with a second side surface of the polycrystalline layer, and each of the first channel layer and the second channel layer has a connection type structure in the first direction between the source and the drain, the first side surface facing the second side surface.

6. The semiconductor device of claim 1, wherein the polycrystalline layer includes a first polycrystalline layer portion adjacent to the source; and a second polycrystalline layer portion adjacent to the drain, and the first polycrystalline layer portion and the second polycrystalline layer portion are spaced apart from each other between the source and the drain.

7. The semiconductor device of claim 1, wherein the grain boundaries of the channel layer are arranged in a direction perpendicular to the first direction.

8. The semiconductor device of claim 1, wherein a hole region, which causes the polycrystalline layer to have the non-connection type structure, is defined between the source and the drain, and the gate is disposed within the hole region.

9. The semiconductor device of claim 1, wherein a plurality of transistors corresponding to the transistor are arranged to be spaced apart from each other in a vertical direction, with an insulating layer positioned between two adjacent transistors among the plurality of transistors in the vertical direction, the vertical direction being perpendicular to the top surface of the substrate.

10. A manufacturing method of a semiconductor device including a transistor, the method comprising:
preparing a polycrystalline layer having a structure with vertically oriented crystal grains over a substrate;
forming a channel layer having a structure with vertically oriented crystal grains using an epitaxial process from a side surface of the polycrystalline layer;
removing a portion of the polycrystalline layer so that the polycrystalline layer has a non-connection type structure in a first direction; and
forming a gate for controlling an electrical characteristic of the channel layer in a region defined by the polycrystalline layer and the channel layer; and
providing a source and a drain on a first portion and a second portion of the channel layer, respectively, and
wherein the polycrystalline layer has the non-connection type structure in the first direction between the source and the drain, the channel layer has a connection type structure in the first direction between the source and the drain, and grain boundaries of the channel layer are arranged in a second direction non-parallel to the first direction between the source and the drain.

11. The manufacturing method of a semiconductor device of claim 10, wherein the preparing of the polycrystalline layer includes:
forming a semiconductor material layer having an amorphous structure or polycrystalline structure; and
heat-treating the semiconductor material layer to grow vertically oriented crystal grains within the semiconductor material layer.

12. The manufacturing method of a semiconductor device of claim 11, wherein the preparing of the polycrystalline layer further includes recessing a portion of the semiconductor material layer in a direction parallel to a top surface of a substrate after the heat-treatment.

13. The manufacturing method of a semiconductor device of claim 10, wherein the channel layer includes:
a first channel layer in contact with a first side surface of the polycrystalline layer; and
a second channel layer in contact with a second side surface of the polycrystalline layer,
the first side surface facing the second side surface,
wherein each of the first channel layer and second channel layer has the connection type structure in the first direction between the source and the drain.

14. The manufacturing method of a semiconductor device of claim 10, wherein the polycrystalline layer includes:
a first polycrystalline layer portion adjacent to the source; and
a second polycrystalline layer portion adjacent to the drain,
wherein the first polycrystalline layer portion and the second polycrystalline layer portion are spaced apart from each other between the source and the drain.

15. The manufacturing method of a semiconductor device of claim 10, further including preparing a stack structure in which the polycrystalline layer and an insulating layer are alternately and repeatedly stacked in a vertical direction perpendicular to a top surface of the substrate, and
wherein a plurality of transistors corresponding to the transistor are arranged to be spaced apart from each other in the vertical direction, and the insulating layer is disposed between two adjacent transistors among the plurality of transistors in the vertical direction.

16. A three-dimensional memory device including a plurality of memory cells stacked over a substrate,
wherein each of the plurality of memory cells includes a transistor and a capacitor connected to the transistor,
wherein the transistor includes:
a polycrystalline layer having a structure with vertically oriented crystal grains;
a channel layer in contact with a side surface of the polycrystalline layer and having a structure with vertically oriented crystal grains;
a source and a drain provided on a first portion and a second portion of the channel layer, respectively; and
a gate configured to control an electrical characteristic of the channel layer, and
wherein the polycrystalline layer has a non-connection type structure in a first direction between the source and the drain, the channel layer has a connection type structure in the first direction between the source and the drain, and grain boundaries of the channel layer are arranged in a second direction non-parallel to the first direction between the source and the drain, the first direction and the second direction being parallel to a top surface of the substrate.

17. The three-dimensional memory device of claim 16, wherein the polycrystalline layer and the channel layer have a columnar crystal grain structure.

18. The three-dimensional memory device of claim 16, wherein the channel layer includes a first channel layer in contact with a first side surface of the polycrystalline layer; and a second channel layer in contact with a second side surface of the polycrystalline layer, and each of the first channel layer and the second channel layer has a connection type structure in the first direction between the source and the drain, the first side surface facing the second side surface.

19. The three-dimensional memory device of claim 16, wherein the polycrystalline layer includes a first polycrystalline layer portion adjacent to the source; and a second polycrystalline layer portion adjacent to the drain, and the first polycrystalline layer portion and the second polycrystalline layer portion are spaced apart from each other between the source and the drain.

20. The three-dimensional memory device of claim 16, wherein the grain boundaries of the channel layer are arranged in a direction perpendicular to the first direction.

21. The three-dimensional memory device of claim 16, wherein an insulating layer is disposed between the plurality of transistors and between the plurality of capacitors in the vertical direction perpendicular to the top surface of the substrate.

22. The three-dimensional memory device of claim 16, further comprising a plurality of bit lines connected to the plurality of memory cells, respectively, and extending in a horizontal direction parallel to the top surface of the substrate.

23. A manufacturing method of three-dimensional memory device comprising:
preparing, over a substrate, a patterned stack structure including a stack structure pattern in which an insulating layer and a first semiconductor material layer are alternately and repeatedly stacked in a vertical direction, wherein the first semiconductor material layer has a structure with vertically oriented crystal grains, the vertical direction being perpendicular to a top surface of the substrate;
forming a first recess region by recessing the first semiconductor material layer in the stack structure pattern to a certain depth in a horizontal direction parallel to the top surface of the substrate;
forming a second semiconductor material layer having a structure with vertically oriented crystal grains using an epitaxial process from a side surface of the first semiconductor material layer in the first recess region;
forming a first vertical hole in a transistor formation region of the stack structure pattern;
forming a gate insulating layer in the first vertical hole;
forming a gate filling the first vertical hole after the gate insulating layer is formed;
forming an opening in a region adjacent to the transistor formation region of the stack structure pattern and forming a first etched region by recessing, in the horizontal direction, the first and second semiconductor material layers exposed by the opening;
forming a bit line in the first etched region;
forming a second vertical hole in a capacitor formation region of the stack structure pattern;
forming a second etched region by recessing, in the horizontal direction, the first and second semiconductor material layers exposed by the second vertical hole, defining a polycrystalline layer patterned from the first semiconductor material layer in the transistor formation region, and defining a channel layer patterned from the second semiconductor material layer in the transistor formation region; and
forming a capacitor structure in the second etched region and the second vertical hole, and
wherein a source and a drain are provided on a first portion and a second portion of the channel layer, respectively, the polycrystalline layer has a non-connection type structure in a first direction between the source and the drain, the channel layer has a connection type structure in the first direction between the source and the drain, and grain boundaries of the channel layer are arranged in a second direction non-parallel to the first direction between the source and drain, the first and the second directions being parallel to the top surface of the substrate.

24. The manufacturing method of three-dimensional memory device of claim 23, wherein the preparing of the patterned stack structure comprises:
forming a stack structure in which the insulating layer and a semiconductor material layer having an amorphous structure or polycrystalline structure are alternately and repeatedly stacked in the vertical direction;
heat-treating the semiconductor material layer to grow and vertically orient grains within the semiconductor material layer; and
performing a cell patterning process on the stack structure.

25. The manufacturing method of three-dimensional memory device of claim 23, wherein the polycrystalline layer and the channel layer have a columnar crystal grain structure.

26. The manufacturing method of three-dimensional memory device of claim 23, wherein the grain boundaries of the channel layer are arranged in a direction perpendicular to the first direction.

27. The manufacturing method of three-dimensional memory device of claim 23, wherein the forming of the capacitor structure includes:
forming a first electrode in the second etched region;
forming a dielectric layer in the second vertical hole; and
forming a second electrode filling the second vertical hole.
